(19) United States
(12) Patent Application Publication
(10) Pub. No.: US 2020/0401044 A1
(43) Pub. Date: Dec. 24, 2020

(54) PATTERN-FORMING MATERIAL, PATTERN-FORMING METHOD, AND MONOMER FOR PATTERN-FORMING MATERIAL

(71) Applicant: OJI HOLDINGS CORPORATION, Tokyo (JP)

(72) Inventors: Kazuyo MORITA, Tokyo (JP); Kimiko HATTORI, Tokyo (JP)

(73) Assignee: OJI HOLDINGS CORPORATION, Tokyo (JP)

(21) Appl. No.: 16/975,609

(22) PCT Filed: Feb. 25, 2019
(86) PCT No.: PCT/JP2019/006949

§ 371 Date: Aug. 25, 2020

(30) Foreign Application Priority Data
Feb. 26, 2018 (JP) 2018-032282

(51) Int. Cl. G03F 7/039; G03F 7/11; G03F 7/075; C08F 20/26

(52) U.S. Cl. CPC G03F 7/039; C08F 20/26; G03F 7/0757; G03F 7/11

(57) ABSTRACT

An object of the present invention is to provide a pattern-forming film having excellent etching resistance. The present invention relates to a pattern-forming material including a polymer containing oxygen atoms, in which the polymer has an oxygen atom content of 20% by mass or more with respect to the total mass of the polymer, and the polymer has a silicon atom content of 10% by mass or less with respect to the total mass of the polymer.

### TECHNICAL FIELD

The present invention relates to a pattern-forming material, a pattern-forming method, and a monomer for a pattern-forming material.

### BACKGROUND ART

Electronic devices such as semiconductors are required to be highly integrated due to miniaturization. Regarding the patterns of semiconductor devices, miniaturization and diversification of shapes are being studied. Known methods for forming such a pattern include a lithography method using a photoresist and a pattern-forming method involving self-assembly using directed self-assembly materials. For example, a lithography method using a photoresist is a processing method in which a photoresist pattern is obtained by forming a photoresist thin film is formed on a semiconductor substrate such as a silicon wafer, irradiating an actinic ray such as an ultraviolet ray through a mask pattern on which a pattern of a semiconductor device is drawn, and performing development, and then, fine irregularities corresponding to the pattern are formed on the substrate by etching the substrate with the obtained photoresist pattern as a protective film. In addition, the pattern-forming method involving self-assembly is a processing method for forming a thin film using a pattern-forming material, heating the thin film to form a phase-separated structure, and then removing a part of the phase to form a fine pattern.

As a pattern-forming material, for example, a diblock copolymer such as polystyrene-polyethylmethacrylate (PS-PMMA) is known. For example, Patent Literature 1 discloses a method for forming a resist mask layer by a sequential infiltration synthesis (SIS) method using PS-PMMA as a pattern-forming material.

Meanwhile, in order to form a fine pattern, a method for forming a pattern after forming an underlayer film on a substrate such as a silicon wafer has also been studied. For example, Patent Literature 2 discloses a composition for forming a resist underlayer film, which contains polysiloxane [A] and a solvent [B], and the solvent [B] contains a tertiary alcohol (B1). Further, Patent Literature 3 discloses a method for forming a resist underlayer film, comprising a coating step of coating a composition for forming a resist underlayer film on a substrate, and a heating step of heating the obtained coating film in an atmosphere having an oxygen concentration of less than 1% by volume at a temperature higher than 450° C. to 800° C., wherein the composition for forming a resist underlayer film contains a compound having an aromatic ring.

### CITATION LIST

### Patent Literature

Patent Literature 1: US Patent Publication No. 2012/241411

Patent Literature 2: JP Patent Publication No. 2016-170338 A

Patent Literature 3: JP Patent Publication No. 2016-206676 A

### SUMMARY OF INVENTION

### Technical Problem

After forming a pattern using the pattern-forming material or the compassion for forming a resist underlayer film as described above, an etching step of processing the pattern shape on a silicon wafer substrate may be further performed using the pattern as a protective film. However, there were problems that a protective film formed by using the conventional pattern-forming material or the composition for forming a resist underlayer film does not have sufficient etching resistance and the pattern workability on the substrate is not sufficient. For example, in a case where a protective film is formed using a pattern-forming material or a composition for forming a resist underlayer film, the protective film itself is also scraped during the etching step of processing a substrate, which may make it difficult to perform fine pattern processing.

In order to solve the problems of the prior art, the present inventors have conducted studies for the purpose of forming a pattern-forming film having excellent etching resistance.

### Solution to Problem

As a result of assiduous studies made for the purpose of solving the above-mentioned problems, the present inventors have found that a pattern-forming film having excellent etching resistance can be obtained by using a polymer having a high oxygen content as the polymer contained in the pattern-forming material.

Specifically, the present invention has the following constitution.

[1] A pattern-forming material comprising a polymer containing oxygen atoms,

wherein the polymer has an oxygen atom content of 20% by mass or m ore with respect to the total mass of the polymer, and

the polymer has a silicon atom content of 10% by mass or less with respect to the total mass of the polymer.

[2] The pattern-forming material according to [1], which is for metal introduction.
[3] The pattern-forming material according to [1] or [2], wherein the polymer contains at least one selected from a unit derived from a sugar derivative and a unit derived from a (meth)acrylate.
[4] The pattern-forming material according to any one of [1] to [3], wherein the polymer contains a unit derived from a sugar derivative.
[5] The pattern-forming material according to [4], wherein the sugar derivative is at least one selected from a pentose derivative and a hexose derivative.
[6] The pattern-forming material according to any one of [1] to [5], which further comprises an organic solvent.
[7] The pattern-forming material according to any one of [1] to [6], which i s used for forming an underlayer film.
[8] The pattern-forming material according to any one of [1] to [6], which i s used for forming a self-assembled film.
[9] The pattern-forming material according to any one of [1] to [6], which i s used for forming a resist film.
[10] A pattern-forming method, comprising:

forming a pattern-forming film using the pattern-forming material according to any one of claims 1 to 6; and

removing a part of the pattern-forming film.

[11] The pattern-forming method according to [10], comprising:

introducing a metal into the pattern-forming film.

[12] A monomer for a pattern-forming material, which is represented by the following formula (1′) or the following formula (2′):

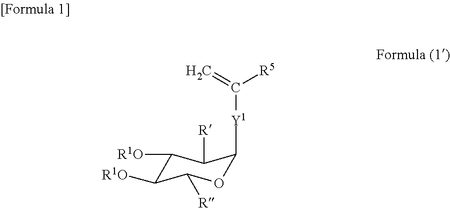

wherein, in the formula (1′), each R¹ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R¹ may be the same or different;

R′ represents a hydrogen atom, —OR¹¹, or —NR¹²;

R″ represents a hydrogen atom, —OR¹¹, —COOR¹³, or —CH₂OR¹³, provided that R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, a plurality of R¹² may be the same or different, and R¹³ represents a hydrogen atom, an alkyl group, an acyl group, an aryl group, a trimethylsilyl group, or a phosphoryl group;

R⁵ represents a hydrogen atom or an alkyl group; and

each Y¹ independently represent a single bond or a linking group;

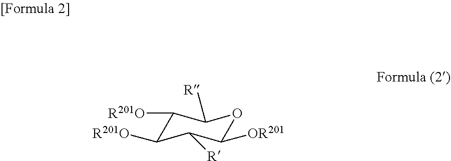

wherein, in the formula (2′), each R²⁰¹ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R²⁰¹ may be the same or different;

R′ represents a hydrogen atom, —OR¹¹, or —NR¹²; and

R″ represents a hydrogen atom, —OR¹¹, —COOR¹¹, or —CH₂OR¹³, provided that R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, a plurality of R¹² may be the same or different, and R¹³ represents a hydrogen atom, an alkyl group, an acyl group, an aryl group, a trimethylsilyl group, or a phosphoryl group.

### Effects of Invention

According to the present invention, a pattern-forming material capable of forming a pattern-forming film having excellent etching resistance can be obtained. That is to say, a pattern-forming film (protective film) formed using the pattern-forming material of the present invention can exhibit excellent etching resistance in the etching step of processing a substrate.

### BRIEF DESCRIPTION OF DRAWINGS

FIG. 1 is a cross-sectional view for illustrating an example of a structure composed of a substrate and a pattern-forming film (underlayer film).

FIG. 2 is a cross-sectional view for illustrating an example of a structure composed of a substrate and a pattern-forming film (self-assembled film).

FIG. 3 is a cross-sectional view for illustrating an example of a structure composed of a substrate and a pattern-forming film (resist film).

### DESCRIPTION OF EMBODIMENTS

The present invention is described in detail hereinunder. The description of the constitutive elements of the invention given hereinunder is for some typical embodiments and examples of the invention, but the invention should not be limited to such embodiments. In this description, the numerical range expressed by the wording “a number to another number” means the range that falls between the former number indicating the lower limit value of the range and the latter number indicating the upper limit value thereof.

In addition, with regard to a substituent described herein for which substitution/non-substitution is not specified, it means that the group may have an arbitrary substituent. Moreover, the term “(meth)acrylate” used herein is meant to include both “acrylate” and “methacrylate.”

(Pattern-Forming Material)

The present invention relates to a pattern-forming material comprising a polymer containing oxygen atoms. The polymer described herein has an oxygen atom content of 20% by mass or more with respect to the total mass of the polymer. In addition, the polymer has a silicon atom content of 10% by mass or less with respect to the total mass of the polymer.

The pattern-forming material of the present invention can form a pattern-forming film having excellent etching resistance by using a polymer having the above configuration. Since the pattern-forming material of the present invention contains a polymer into which a large amount of metal can be introduced, the etching resistance of the pattern-forming film can be increased.

As described above, the pattern-forming material of the present invention contains a polymer into which a large amount of metal can be introduced. That is to say, a large amount of metal can also be introduced into the pattern-forming material of the present invention. Therefore, it can be said that the pattern-forming material of the present invention is a material for metal introduction. The polymer contained in the pattern-forming material reacts (bonds) to a metal, thereby forming a pattern-forming film containing a metal. Such a pattern-forming film becomes harder than a pattern-forming film containing no metal, and thus, it can exhibit excellent etching resistance. Here, it is preferable that the polymer contained in the pattern-forming material reacts (bonds) with a metal at a plurality of sites in one molecule of the polymer, and the more the number of sites for reacting (bonding) with the metal, the higher the metal introduction rate. In the present invention, the metal introduction rate is increased by reacting (bonding)oxygen atoms contained in the polymer and metal atoms, and such a high metal introduction rate is achieved by setting the oxygen atom content in the polymer to a predetermined value. The bonding between oxygen atoms contained in the polymer and metal atoms is not particularly limited, but for example, the bonding between oxygen atoms contained in the polymer and metal atoms is preferably coordinate bonding or ionic bonding.

The metal introduction rate in the pattern-forming film is preferably 5 at % (atomic percent) or more, more preferably 10 at % or more, even more preferably 20 at % or more, and particularly preferably 22 at % or more. The metal introduction rate can be calculated, for example, by the following method. First, a pattern-forming film formed of a pattern-forming material is placed in an atomic layer deposition apparatus (AU), and Al(CH₃)₃ gas is introduced therein at 95° C., and then steam is introduced. By repeating this operation three times, Al is introduced into the pattern-forming film. EDX analysis (energy dispersive X-ray analysis) is performed on the pattern-forming film after introduction of Al by using an electron microscope JSM7800F (manufactured by JEOL Ltd.) to calculate an Al component ratio (Al content ratio), which is used as a metal introduction rate.

The pattern-forming film formed from the pattern-forming material of the present invention is, for example, a film (protective film) provided on a substrate for forming a pattern on a substrate such as a silicon wafer. The pattern-forming film may be a film provided on the substrate so as to be in direct contact therewith, or may be a film laminated on the substrate via another layer. The pattern-forming film is processed into a pattern shape which is desired to be formed on the substrate, and the portion left as the pattern shape serves as a protective film in the subsequent etching step. Then, ater the pattern is formed on the substrate, the pattern-forming film (protective film) is usually removed from the substrate. Thus, the pattern-forming film is used in the step of forming a pattern on the substrate.

The pattern-forming film formed from the pattern-forming material of the present invention exhibits excellent etching resistance when processing a pattern shape on a substrate, and the etching resistance of such a pattern-forming film can be evaluated based on, for example, an etching selectivity calculated by the following equation.

Etching selectivity=Depth of etched portion of substrate/(Thickness of pattern−forming film before etching treatment−Thickness of pattern-forming film after etching treatment)

The depth of the etched portion of the substrate and the thickness of the pattern-forming film before and after the etching treatment can be measured by, for example, observing a cross section with a scanning electron microscope (SEM). The depth of the etched portion of the substrate is the maximum depth of the portion cut by etching treatment, and the thickness of the pattern-forming film before and after the etching treatment is the maximum thickness of the remaining portion of the pattern-forming film. The etching selectivity calculated as described above is preferably greater than 2, more preferably 3 or more, and even more preferably 4 or more. The upper limit of the etching selectivity is not particularly limited, but can be set to 200, for example.

Further, the pattern-forming material of the present invention may be used as a material for forming a photomask for forming a pattern. A photomask is formed by applying at least the pattern-forming material of the present invention on a photomask substrate to form a predetermined pattern, and performing steps such as etching and resist stripping.

<Polymer>

The pattern-forming material of the present invention contains a polymer containing oxygen atoms. The oxygen atom content of the polymer may be 20% by mass or more, preferably 22% by mass or more, more preferably 25% by mass or more, still more preferably 30% by mass or more, even more preferably 33% by mass or more, and particularly preferably 35% by mass or more with respect to the total mass of the polymer. The upper limit of the oxygen atom content of the polymer is not particularly limited, but may be 70% by mass, for example. The oxygen atom content of the polymer can be calculated using an elemental analyzer, for example. As the elemental analyzer, for example, a 2400IICHNS/O fully automatic elemental analyzer manufactured by Perkin Elmer Co., Ltd. can be used.

The silicon atom content of the polymer may be 10% by mass or less with respect to the total mass of the polymer, and it is preferably 5% by mass or less. It is preferable that the polymer does not substantially contain silicon atoms, and the silicon atom content of the polymer may be 0% by mass. The silicon atom content can be determined by performing ICP emission spectrometry.

The polymer preferably consists of an organic material. This is preferable from the viewpoint of favorable adhesion to an organic resist material or the like as compared with the case where the polymer contains an organic-inorganic hybrid material such as polysiloxane.

The polymer preferably contains at least one selected from a unit derived from a sugar derivative and a unit derived from a (meth)acrylate. In this case, the oxygen atom content of the sugar derivative is preferably 20% by mass or more, and similarly, the oxygen atom content of the (meth)acrylate is preferably 20% by mass or more. Among them, the polymer preferably contains a unit derived from a sugar derivative.

The weight average molecular weight (Mw) of the polymer is preferably 500 or more, more preferably 1000 or more, and even more preferably 1500 or more. The weight average molecular weight (Mw) of the polymer is preferably 1,000,000 or less, more preferably 500,000 or less, still more preferably 300,000 or less, and even more preferably 250,000 or less. The weight average molecular weight (Mw) of the polymer is a value measured in terms of polystyrene by GPC.

The ratio (Mw/Mn) of the weight average molecular weight (Mw) and the number average molecular weight (Mn) of the polymer is preferably 1 or more. Further, Mw/Mn is preferably 52 or less, more preferably 10 or less, still more preferably 8 or less, even more preferably 4 or less, and particularly preferably 3 or less.

The solubility of the polymer in at least one selected from PGMEA, PGME, THF, butyl acetate, anisole, cyclohexanone, ethyl lactate, N-methylpyrrolidone, γ-butyrolactone, and DMF is preferably 1% by mass or more, more preferably 2% by mass or more, even more preferably 3% by mass or more, and particularly preferably 4% by mass or more. The upper limit of the solubility of the polymer in the organic solvent is not particularly limited, but can be 40% by mass, for example. The solubility refers to solubility in at least one selected from PGMEA, PGME, THF, buty acetate, anisole, cyclohexanone, ethyl lactate, N-methylpyrrolidone, γ-butyrolactone, and DMF.

The solubility of a polymer can be measured by adding PGMEA, PGME, THF, butyl acetate, anisole, cyclohexanone, ethyl lactate, N-methylpyrrolidone, γ-butyrolactone, or DMF to a predetermined amount of the polymer while stirring and dissolving, and recording the amount of the organic solvent added. A magnetic stirrer or the like may be used for stirring. Then, the solubility is calculated from the following equation.

Solubility (% by mass)=Mass of polymer/Amount of organic solvent when dissolved×100

The content of the polymer is preferably 0.1% by mass or more, and more preferably 1% by mass or more with respect to the total mass of the pattern-forming material. Further, the content of the polymer is preferably 90% by mass or less, more preferably 80% by mass or less, and even more preferably 70% by mass or less with respect to the total mass of the pattern-forming material.

<<Sugar Derivatives>>

The polymer preferably contains a unit derived from a sugar derivative. The term “unit” used herein refers to a repeat unit (monomer unit) that constitutes the main chain of the polymer. However, the side chain of the unit derived from one sugar derivative may further include a unit derived from the sugar derivative, and in this case, the repeat unit (monomer unit) constituting the polymer of the side chain is also equivalent to the “unit” used herein.

In a case where the polymer contains a unit derived from a sugar derivative, the content (% by mass) of units derived from a sugar derivative is preferably 1% by mass to 95% by mass, more preferably 3% by mass to 90% by mass, even more preferably 7% by mass to 85% by mass, and particularly preferably 12% by mass to 80% by mass with respect to the total mass of the polymer.

The content of units derived from a sugar derivative can be determined from, for example, ¹H-NMR and the weight average molecular weight of the polymer. Specifically, it can be calculated using the following equation.

Content of units derived from sugar derivative (% by mass)=Mass of units derived from sugar derivative×Number of units (monomer) derived from sugar derivative/Weight average molecular weight of polymer

The sugar derivative is preferably at least one selected from a pentose derivative and a hexose derivative.

The pentose derivative is not particularly limited as long as it has a petose-derived structure in which the hydroxyl group of pentose of a known monosaccharide or polysaccharide is modified with at least a substituent. The pentose derivative is preferably at least one selected from a hemicellulose derivative, a xylose derivative, and a xylooligosaccharide derivative, and more preferably at least one selected from a hemicellulose derivative and a xylooligosaccharide derivative.

The hexose derivative is not particularly limited as long as it has a hexose-derived structure in which the hydroxyl group of hexose of a known monosaccharide or polysaccharide is modified with at least a substituent. The hexose derivative is preferably at least one selected from a glucose derivative and a cellulose derivative, and more preferably a cellulose derivative.

Above all, the sugar derivative is preferably at least one selected from a cellulose derivative, a hemicellulose derivative, and a xylooligosaccharide derivative. That is to say, the polymer preferably contains at least one selected from a unit derived from a cellulose derivative, a unit derived from a hemicellulose derivative, and a unit derived from a xylooligosaccharide derivative. Above all, the polymer more preferably contains a unit derived from a xylooligosaccharide derivative because the oxygen atom content in the molecule is high and the number of metal-binding sites is large.

The unit derived from a sugar derivative may be a constitutional unit having a sugar derivative-derived structure in its side chain or may be a constitutional unit having a sugar derivative-derived structure in its main chain. In a case where the unit derived from a sugar derivative is a constitutional unit having a sugar derivative-derived structure in its side chain, the unit derived from a sugar derivative preferably has a structure represented by the formula (1) described later. Also in a case where the unit derived from a sugar derivative is a constitutional unit having a sugar derivative-derived structure in its main chain, the unit derived from a sugar derivative preferably has a structure represented by the formula (2) described later. Above all, the unit derived from a sugar derivative preferably has a structure represented by the formula (1) from the viewpoint that its main chain is not excessively long and the solubility of the polymer in an organic solvent is easily increased. Note that, in the formulae (1) and (2), the structure of a sugar derivative is described as a cyclic structure, but the structure of a sugar derivative is not limited to a cyclic structure and may be an open ring structure (chain structure) called aldose or ketose.

The structure represented by the formula (1) will be described below.

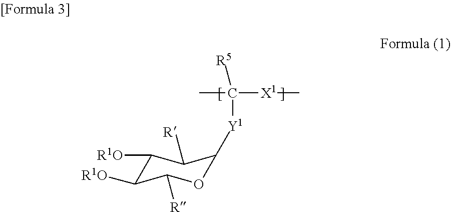

wherein, in the formula (1), each R¹ independently represents a hydrogen atom, a fluorine atom, a chlorine atom, a bromine atom, an iodine atom, an alkyl group, an acyl group, an aryl group, a trimethylsilyl group, or a phosphoryl group, the alkyl group may include a sugar derivative group, and a plurality of R¹ may be the same or different.

R′ represents a hydrogen atom, —OR¹¹, or —NR¹²₂.

R″ represents a hydrogen atom, —OR¹¹, —COOR¹³, or —CH₂OR¹³. R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, and a plurality of R¹² may be the same or different, and R¹³ represents a hydrogen atom, an alkyl group, an acyl group, an aryl group, a trimethylsilyl group, or a phosphoryl group.

R⁵ represents a hydrogen atom or an alkyl group.

X¹ and Y¹ each independently represent a single bond or a linking group.

In the formula (1), each R¹ independently represents a hydrogen atom, a fluorine atom, a chlorine atom, a bromine atom, an iodine atom, an alkyl group, an acyl group, an aryl group, a trimethylsilyl group, or a phosphoryl group, the alkyl group may include a sugar derivative group, and a plurality of R¹ may be the same or different. Above all, it is preferable that each R¹ is independently a hydrogen atom or an acyl group having 1 to 3 carbon atoms. In a case where the above-described alkyl group is an alkyl group having a substituent, since such an alkyl group includes a sugar derivative group, its sugar chain portion may further have a unit derived from a linear or branched sugar derivative.

The unit derived from a linear or branched sugar derivative is preferably a sugar derivative having the same structure as the sugar derivative to be bonded. Specifically, in a case where R″ in the structure represented by the formula (1) is a hydrogen atom, —OR¹¹, a carboxyl group, or —COOR¹³, and its sugar chain portion (sugar derivative) further has a unit derived from a linear or branched sugar derivative, the unit preferably has a unit derived from a pentose derivative. In a case where R″ of the structure represented by the formula (1) is —CHOR³, and its sugar chain portion (sugar derivative) further has a unit derived from a linear or branched sugar derivative, the unit preferably has a unit derived from a hexose derivative. A substituent that the hydroxyl group of a unit derived from a linear or branched sugar derivative may further have can be the same as the range of R¹.

In the formula (1), R¹ further has a sugar derivative group as at least one alkyl group, meaning that it forms a structure in which a plurality of units derived from a monosaccharide-derived sugar derivative are bonded to each other, which is preferable from the viewpoint of lowering the solubility. In this case, the average degree of polymerization of the sugar derivative (which means the number of monosaccharide-derived sugar derivatives bonded) is preferably 1 to 20, more preferably 15 or less, and even more preferably 12 or less.

In a case where R¹ is an alkyl group or an acyl group, the number of carbon atoms can be appropriately selected according to the purpose. For example, the number of carbon atoms is preferably 1 or more, and it is preferably 200 or less, more preferably 100 or less, even more preferably 20 or less, and particularly preferably 4 or less.

Specific examples of R¹ include: acyl groups such as an acetyl group, a propanoyl group, a butyryl group, an isobutyryl group, a valeryl group, an isovaleryl group, a pivaloyl group, a hexanoyl group, an octanoyl group, a chloroacetyl group, a trifluoroacetyl group, a cyclopentanecarbonyl group, a cyclohexanecarbonyl group, a benzoyl group, a methoxybenzoyl group, and a chlorobenzoyl group; and alkyl groups such as a methyl group, an ethyl group, an n-propyl group, an n-butyl group, an i-butyl group, and a t-butyl group; and a trimethylsilyl group. Of these, a methyl group, an ethyl group, an acetyl group, a propanoyl group, an n-butyryl group, an isobutyryl group, a benzoyl group, and a trimethylsilyl group are preferable, and an acetyl group and a propanoyl group are particularly preferable.

In the formula (1), R′ represents a hydrogen atom, —OR¹¹, or —NR¹². R¹¹ represents a hydrogen atom, an alkyl group, an acyl group, an aryl group, a trimethylsilyl group, or a phosphoryl group. In a case where R¹¹ is an alkyl group or an acyl group, the number of carbon atoms can be appropriately selected according to the purpose. For example, the number of carbon atoms is preferably 1 or more, and it is preferably 200 or less, more preferably 100 or less, even more preferably 20 or less, and particularly preferably 4 or less. Above all, R¹¹ is preferably a hydrogen atom, an alkyl group having 1 to 3 carbon atoms, or an acyl group or a trimethylsilyl group having 1 to 3 carbon atoms. Specific examples of R¹¹ include: acyl groups such as an acetyl group, a propanoyl group, a butyryl group, an isobutyryl group, a valeryl group, an isovaleryl group, a pivaloyl group, a hexanoyl group, an octanoyl group, a chloroacetyl group, a trifluoroacetyl group, a cyclopentanecarbonyl group, a cyclohexanecarbonyl group, a benzoyl group, a methoxybenzoyl group, and a chlorobenzoyl group; and alkyl groups such as a methyl group, an ethyl group, an n-propyl group, an n-butyl group, an i-butyl group, and a t-butyl group; and a trimethylsilyl group. Of these, a methyl group, an ethyl group, an acetyl group, a propanoyl group, an n-butyryl group, an isobutyryl group, a benzoyl group, and a trimethylsilyl group are preferable, and an acetyl group and a propanoyl group are particularly preferable.

R¹² represents a hydrogen atom, an alkyl group, a carboxyl group, or an acyl group, and a plurality of R¹² may be the same or different. Above all, R² is preferably a hydrogen atom or an alkyl group having 1 to 3 carbon atoms, or a carboxyl group-COOH or —COCH₃.

A preferable structure of R′ is —H, —OH, —OAc, —OCOC₂H₅, —OCOC₆H₅, —NH₂, —NHCOOH, or —NHCOCH₃, a more preferable structure of R′ is —H, —OH, —OAc, —OCOC₂H₅, or —NH₂, and a particularly preferable structure of R′ is —OH, —OAc, or —OCOC₂H₅.

In the formula (1), R″ represents, a hydrogen atom, —OR¹¹, a carboxyl group, —COOR¹³, or —CH₂OR¹³. R¹³ represents a hydrogen atom, an alkyl group, an acyl group, an aryl group, a trimethylsilyl group, or a phosphoryl group. In a case where ¹³ is an alkyl group or an acyl group, the number of carbon atoms can be appropriately selected according to the purpose. For example, the number of carbon atoms is preferably 1 or more, and it is preferably 200 or less, more preferably 100 or less, even more preferably 20 or less, and particularly preferably 4 or less. Above all, R¹³ is preferably a hydrogen atom or an acyl group or a trimethylsilyl group having 1 to 3 carbon atoms.

Specific examples of R¹¹ include: acyl groups such as an acetyl group, a propanoyl group, a butyryl group, an isobutyryl group, a valeryl group, an isovaleryl group, a pivaloyl group, a hexanoyl group, an octanoyl group, a chloroacetyl group, a trifluoroacetyl group, a cyclopentanecarbonyl group, a cyclohexanecarbonyl group, a benzoyl group, a methoxybenzoyl group, and a chlorobenzoyl group; and alkyl groups such as a methyl group, an ethyl group, an n-propyl group, an n-butyl group, an i-butyl group, and a t-butyl group; and a trimethylsilyl group. Of these, a methyl group, an ethyl group, an acetyl group, a propanoyl group, an n-butyryl group, an isobutyryl group, a benzoyl group, and a trimethylsilyl group are preferable, and an acetyl group and a propanoyl group are particularly preferable.

A preferable structure of R″ is —H, —OAc. —OCOC₂H₅, —COOH, —COOCH₃, —COOC₂H, —CH₂OH, —CH₂OAc, or —CH₂OCOC₂H₅, a more preferable structure of R″ is —H, —OAc, —OCOC₂H₅, —COOH, —CH₂OH, —CH₂OAc, or —CH₂OCOC₂H₅, and a particularly preferable structure of R″ is —H, —CH₂OH, or —CH₂OAc.

In the formula (1), R represents a hydrogen atom or an alkyl group. Above all, R⁵ is preferably a hydrogen atom or an alkyl group having 1 to 3 carbon atoms, and particularly preferably a hydrogen atom or a methyl group.

In the formula (1), X¹ and Y¹ each independently represent a single bond or a linking group.

In a case where X¹ is a linking group, examples of X¹ include groups such as an alkylene group, —O—, —NH₂—, and a carbonyl group, while X¹ is preferably a single bond or an alkylene group having 1 to 6 carbon atoms, and more preferably an alkylene group having 1 to 3 carbon atoms.

In a case where Y¹ is a linking group, examples of Y¹ include groups such as an alkylene group, a phenylene group, —C—, and —C(═O)O—. Y¹ may be a linking group formed by combining these groups. Above all, Y¹ is preferably a linking group represented by the following structural formula.

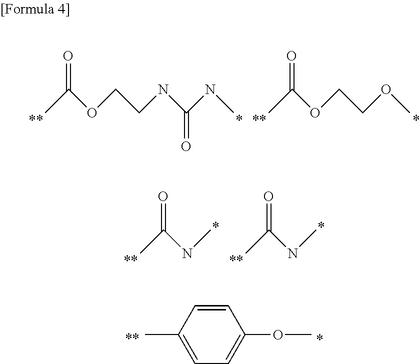

In the above structural formula, a double asterisk (**) indicates the binding site to the main chain side, and a single asterisk (*) indicates the binding site to the sugar unit on the side chain.

The structure represented by the formula (2) will be described below.

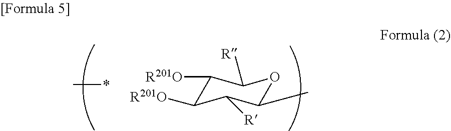

wherein, in the formula (2), each R²⁰¹ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R²¹ may be the same or different;

R′ represents a hydrogen atom, —OR¹¹, or —NR¹²₂.

R″ represents a hydrogen atom, —OR¹¹, —COOR¹³, or —CH₂OR¹³. R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, and a plurality of R¹² may be the same or different, and R¹³ represents a hydrogen atom, an alkyl group, an acyl group, an aryl group, a trimethylsilyl group, or a phosphoryl group.

The asterisk (*) represents a binding site with any one of oxygen atoms to which R²⁰¹ is bound, instead of R²⁰¹.

In the formula (2), preferable ranges of R²⁰¹, R′, and R″ are the same as the preferable ranges of R¹, R′, and R″ in the formula (1).

In addition, R¹, R′, and R″ can be returned to hydrogen atoms by reduction from the polymer after polymerization, and thus, R¹ and R¹¹ can be hydrogen. However, R¹ and R¹¹ may not all be reduced.

<<(Meth)acrylate>>

The polymer may include a unit derived from a (meth)acrylate. The unit derived from a (meth)acrylate is preferably, for example, a unit represented by the following formula (3).

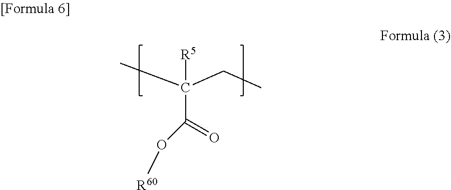

In the formula (3), R⁵ represents a hydrogen atom or an alkyl group, and R⁶⁰ represents an alkyl group which may have a substituent or an aryl group which may have a substituent.

In the formula (3), R⁵ is preferably a hydrogen atom or an alkyl group having 1 to 3 carbon atoms, and particularly preferably a hydrogen atom or a methyl group.

In the formula (3), R⁶⁰ is preferably an alkyl group which may have a substituent. The alkyl group preferably has 1 to 8 carbon atoms, more preferably 1 to 5 carbon atoms, and even more preferably 1 to 3 carbon atoms. The number of carbon atoms refers to the number of carbon atoms excluding the substituent. Examples of an alkyl group having a substituent may include —CH₂—OH, —CH₂—O-methyl, —CH₂—O-ethyl, —CH₂—O-n-propyl, —CH₂—O-isopropyl, —CH₂—O-n-butyl, —CH₂—O-isobutyl, —CH₂—O-t-butyl, —CH₂—O—(C═O)-methyl, —CH₂—O—(C═O)-ethyl, —CH₂—O—(C═O)-propyl, —CH₂—O—(C═O)-isopropyl, —CH₂—O—(C═O)-n-butyl, —CH₂—O—(C═O)-isobutyl, —CH₂—O—(C═O)-t-butyl, —C₂H₄—OH, —C₂H₄—O-methyl, —C₂H₄—O-ethyl, —C₂H₄—O-n-propyl, —C₂H₄—O-isopropyl, —C₂H₄-O-n-butyl, —C₂H₄—O-isobutyl, —C₂H₄—O-t-butyl, —C₂H₄—O—(C═O)-methyl, —C₂H₄—O—(C═O)-ethyl, —C₂H₄—O—(C═O)-n-propyl, —C₂H₄—O—(C═O)-isopropyl, —C₂H₄—O—(C═O)-n-butyl, —C₂H₄—O—(C═O)-isobutyl, —C₂H₄—O—(C═O)-t-butyl, and —C₂H₄—O—(C═O)—CH₂—(C═O)-methyl. The alkyl group having a substituent may be a cycloalkyl group or a crosslinked cyclic cycloalkyl group.

In a case where the polymer contains a unit derived from a (meth)acrylate, the content (% by mass) of the unit derived from a (meth)acrylate is preferably 1% by mass to 99% by mass, more preferably 3% by mass to 98% by mass, and particularly preferably 12% by mass to 97% by mass with respect to the total mass of the polymer. The content (% by mass) of the unit derived from a (meth)acrylate can be calculated by the same method as the above-described calculation of the content rate of the unit derived from a sugar derivative.

<<Other Constitutional Units>>

The polymer may contain constitutional units other than the unit derived from a sugar derivative and the unit derived from a (meth)acrylate. Examples of other constitutional units include a styrene-derived unit which may have a substituent, a vinylnaphthalene-derived unit, and a lactic acid-derived unit. Further, the other constitutional units are also preferably constitutional units represented by the following formula (4).

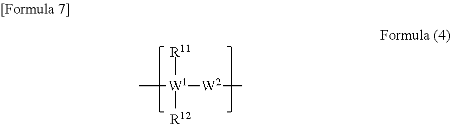

In the formula (4), W¹ represents a carbon atom or a silicon atom.

W² represents —CR₂—, —O—, —COO—, —S—, or —SiR₂— (note that R represents a hydrogen atom or an alkyl group having 1 to 5 carbon atoms, and a plurality of R may be the same or different).
R¹¹ represents a hydrogen atom, a methyl group, an ethyl group, a halogen, or a hydroxyl group.

R¹² represents a hydrogen atom, a hydroxyl group, a cycloalkyl group, an acetyl group, an alkoxy group, a hydroxyalkyloxycarbonyl group, a hydroxyallyloxycarbonyl group, an alkoxycarbonyl group, an aryloxycarbonyl group, an aryl group, or a pyridyl group, and R¹² may further have a substituent.

In the formula (4), W¹ represents a carbon atom or a silicon atom. Above all, W¹ is preferably a carbon atom from the viewpoint that it can form an underlayer film which is difficult to be broken by heat treatment. In addition, in the formula (4), W² represents —CR₂—, —O—, —COO—, —S—, or —SiR₂— (note that R represents a hydrogen atom or an alkyl group having 1 to 5 carbon atoms, and a plurality of R may be the same or different). Above all, W² is preferably —CR₂— or —COO— from the viewpoint that it can form an underlayer film which is difficult to be broken by heat treatment, and it is more preferably —CH₂—.

In the formula (4), R¹¹ represents a hydrogen atom, a methyl group, a halogen, or a hydroxyl group. R¹¹ is more preferably a hydrogen atom or a methyl group, and even more preferably a hydrogen atom. In addition, in the formula (4). R represents a hydrogen atom, a hydroxyl group, an acetyl group, a methoxycarbonyl group, an aryl group, or a pyridyl group. R¹² is preferably a cycloalkyl group, an aryl group, or a pyridyl group, more preferably a cycloalkyl group or an aryl group, and even more preferably a phenyl group. The phenyl group is also preferably a phenyl group having a substituent. Examples of a phenyl group having a substituent may include a 4-t-butylphenyl group, a methoxyphenyl group, a dimethoxyphenyl group, a trimethoxyphenyl group, a trimethylsilylphenyl group, and tetramethyldisilylphenyl group. In addition, R¹² is also preferably a naphthyl group. In a case where R¹² is a cycloalkyl group, it may be a crosslinked cyclic cycloalkyl group.

Above all, R¹² is preferably a phenyl group, and R¹² is particularly preferably a styrene polymer. Examples of an aromatic ring-containing unit other than a styrene polymer include the followings. The styrene polymer is a polymer obtained by polymerizing a monomer compound containing a styrene compound. Examples of a styrene compound include styrene, o-methylstyrene, p-methylstyrene, ethylstyrene, p-methoxystyrene, p-phenyl styrene, 2,4-dimethyl styrene, p-n-octyl styrene, p-n-decylstyrene, p-n-dodecylstyrene, chlorostyrene, bromostyrene, trimethylsilystyrene, hydroxystyrene, 3,4,5-methoxystyrene, pentamethyldisilylstyrene, t-butoxycarbonylstyrene, tetrahydropyranylstyrene, phenoxyethylstyrene, and t-butoxycarbonylmethylstyrene. Above all, the styrene compound is preferably at least one selected from styrene and trimethylsilylstyrene, and more preferably styrene. That is to say, the styrene polymer is preferably at least one selected from polystyrene and polytrimethylsilylstyrene, and more preferably polystyrene.

<Copolymer>

The polymer contained in the pattern-forming material of the present invention preferably contains the above-described constitutional unit, and may be a homopolymer consisting of one kind of the above-described constitutional unit, or may be a copolymer containing two or more kinds of the above-described constitutional units. When the polymer is a copolymer, the copolymer may be a block copolymer or a random copolymer. Further, the copolymer may have a structure which partially includes a random copolymer and partially includes a block copolymer. For example, in a case where the pattern-forming material is used for forming a self-assembled film, the polymer is preferably a block copolymer. A block copolymer is preferable from the viewpoint of increasing solubility in an organic solvent, and a random copolymer is preferable from the viewpoint of promoting crosslinking and increasing strength. Therefore, an appropriate structure can be selected as appropriate depending on the application and required physical properties.

In a case where the pattern-forming material of the present invention is used for, for example, forming a self-assembled film, the polymer is preferably a block copolymer. For example, the block copolymer is preferably an A-B type diblock copolymer containing a polymerized portion a and a polymerized portion b, but it may be a block copolymer containing a plurality of polymerized portions a and a plurality of polymerized portions b (e.g., A-B-A-B type). In this case, it is preferable that the polymerized portion a of the copolymer has high hydrophilicity and the polymerized portion b has high hydrophobicity. Specifically, it is preferable that the polymerized portion a of the copolymer is composed of hydrophilic constitutional units represented by the formulae (1) to (3), and the polymerized portion b of the copolymer is composed of hydrophobic constitutional units represented by the formula (4). Above all, it is preferable that the polymerized portion a of the copolymer may be composed of constitutional units represented by the formula (1), and the polymerized portion b of the copolymer may be composed of constitutional units represented by the formula (4).

In a case where the polymerized portion a of the copolymer is composed of the above-described constitutional units represented by the formula (1), and the polymerized portion b of the copolymer is composed of the above-described constitutional units represented by the formula (4), each polymerized portion may be linked via a linking group. Examples of such a linking group include —O—, an alkylene group, a disulfide group, and groups represented by the following structural formulae. In a case where the linking group is an alkylene group, a carbon atom in the alkylene group may be substituted with a hetero atom, and examples of the hetero atom include a nitrogen atom, an oxygen atom, a sulfur atom, and a silicon atom. The length of the linking group is preferably shorter than the length of the polymerized portion a or the polymerized portion b.

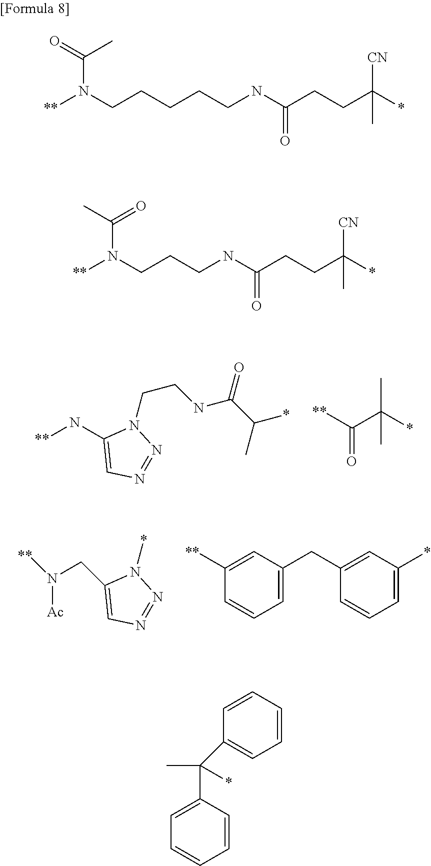

In the above structural formula, a single asterisk (*) indicates the binding site to the polymerized portion b, and a double asterisk (**) indicates the binding site to the polymerized portion a.

Further, the terminal groups of the main chains of the polymerized portions a and b can be, for example, a hydrogen atom or a substituent. The terminal groups of the main chains of the polymerized portions a and b may be the same or different. Examples of a substituent include: a fluorine atom, a chlorine atom, a bromine atom, an iodine atom; acyl groups such as a hydroxyl group, an amino group, an acetyl group, a propanoyl group, a butyryl group, an isobutyryl group, a valeryl group, an isovaleryl group, a pivaloyl group, a hexanoyl group, an octanoyl group, a choroacetyl group, a trifluorocetyl group, a cyclopentanecarbonyl group, a cyclohexanecarbonyl group, a benzoyl group, a methoxybenzoyl group, and a chlorobenzoyl group; and alkyl groups such as a methyl group an ethyl group, a propyl group, an n-butyl group, a sec-butyl group, a tert-butyl group, 2-methylbutyronitrile, a cyanovalerinoyl group, a cyclohexyl-1-carbonitrile group a methylpropanoyl group, and an N-butyl-methylpropionamide group; substituents represented by the following structural formulae. The terminal groups of the main chains of the polymerized portions a and b are each independently preferably a hydrogen atom, a hydroxyl group, an acetyl group, a propanoyl group, a butyryl group, an isobutyryl group, an n-butyl group, a sec-butyl group, a tert-butyl group, a 2-methylbutyronitrile, a cyanovalerinoyl group, a cyclohexyl-1-carbonitrile group, a methylpropanoyl group or any of substituents shown below, and particularly preferably a hydrogen atom, a hydroxyl group, a butyl group, or any of substituents shown below.

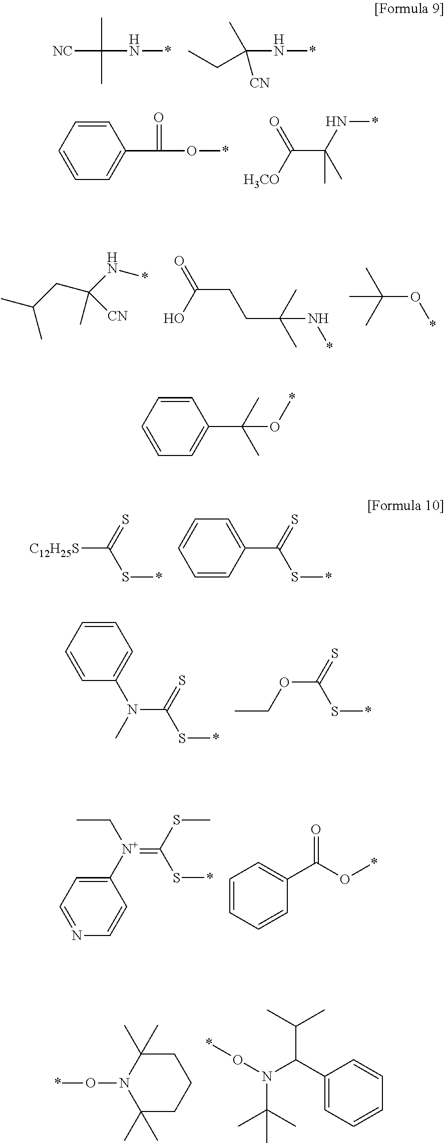

In the above structural formulae, a single asterisk (*) indicates a binding site with the main chain of the copolymer.

The terminal group of the main chain of the polymerized portion b may be a substituent having the structure represented by the above formula (1). That is to say, the copolymer may be a polymer having a polymerized portion a at both ends of the repeat unit, or may be a polymer having an A-B-A type or an A-B-A-B-A type structure. Further, the terminal group of the main chain of the polymerized portion a may be a substituent having the structure represented by the above formula (4). That is to say, the copolymer may be a polymer containing two or more polymerized portions h, or may be a polymer having a B-A-B type or a B-A-B-B-A-B type structure.

(Constituent Ratio)

In a case where the polymer is a copolymer, for example, the content ratio of units derived from a sugar derivative and units derived from a (meth)acrylate is preferably 2:98 to 98:2, more preferably 3:97 to 97:3, and particularly preferably 5:95 to 95:5. The content ratio is the ratio (molar ratio) of the number of units derived from a sugar derivative and the number of units derived from a (meth)acrylate.

<<Synthesis Method of Copolymer>>

The copolymer can be synthesized by a known polymerization method such as living radical polymerization, living anionic polymerization, or atom transfer radical polymerization. For example, in the case of living radical polymerization, a copolymer can be obtained by reacting a monomer with a polymerization initiator such as AIBN (α,α′-azobisisobutyronitrile). In the case of living anionic polymerization, a copolymer can be obtained by reacting butyllithium with a monomer in the presence of lithium chloride. In addition, in the Examples described herein, an example of synthesis using living anionic polymerization or living radical polymerization is shown, but the present invention is not limited thereto, and the synthesis can be appropriately performed by the above-described synthesis methods or known synthesis methods.

Commercially available products may be used as a copolymer and its starting material. Examples thereof include homopolymers such as P9128D-SMMAran, P9128C-SMMAran, Poly(methyl methacrylate), P9130C-SMMAran, P7040-SMMAran, P2405-SMMA, and random polymers or block copolymers manufactured by Polymer Source, Inc. Further, these polymers can be used for carrying out synthesis as appropriate by a known synthesis method.

The polymerized portion a as described above may be obtained by synthesis, but may also be obtained by combining the steps of extraction from lignocellulose or the like derived from a woody plant or a herbaceous plant. In a case where a method of extraction from lignocellulose derived from a woody plant or a herbaceous plant is adopted for obtaining the sugar derivative portion of the polymerized portion a, the extraction method described in JP Patent Publication No. 2012-100546 A is used.

Xylan can be extracted, for example, by the method disclosed in JP Patent Publication No. 2012-180424 A.

Cellulose can be extracted, for example, by the method disclosed in JP Patent Publication No. 2014-148629 A

The polymerized portion a is preferably modified by acetylating or halogenating the OH group of the sugar portion obtained using the above extraction method before use. For example, when introducing an acetyl group, an acetylated sugar derivative portion can be obtained via a reaction with acetic anhydride.

The polymerized portion b may be formed by synthesis, or a commercially available product may be used. When polymerizing the polymerization portion b, a known synthesis method can be adopted. When using a commercially available product, for example, Amino-terminated PS (Mw=12300 Da, Mw/Mn=1.02, manufactured by Polymer Source, Inc.) can be used.

A copolymer can be synthesized with reference to Macromolecules Vol. 36, No. 6, 2003. Specifically, a compound containing the polymerized portion a and a compound containing the polymerized portion b are put in a solvent containing DMF, water, acetontrile, and the like, and a reducing agent is added thereto. Examples of a reducing agent include NaCNBH₃. Then, the mixture is stirred at 30° C. to 100° C. for 1 day to 20 days, and a reducing agent is appropriately added if necessary. A copolymer can be obtained by adding water to obtain a precipitate and vacuum-drying the solid content.

As a method for synthesizing a copolymer, in addition to the above-described methods, a synthesis method using radical polymerization, RAFT polymerization, ATRP polymerization, click reaction, or NMP polymerization can be mentioned.

Radical polymerization is a polymerization reaction that occurs by adding an initiator to generate two free radicals by a thermal reaction or a photoreaction. A monomer (e.g., a sugar methacrylate compound in which methacrylic acid is added to the terminal position β-1 of a xylooligosaccharide-styrene monomer) and an initiator (e.g., an azo compound such as azobisbutyronitrile (AIBN)) are heated at 150° C. such that a polystyrene-polysaccharide methacrylate random copolymer can be synthesized.

RAFT polymerization is a radical-initiated polymerization reaction involving an exchange chain reaction utilizing a thiocarbonylthio group. For example, the method for synthesizing a copolymer by converting the OH group at the terminal position 1 of xylooligosaccharide into a thiocarbonylthio group, and then reacting a styrene monomer at 30° C. to 100° C. can be adopted (Material Matters vol. 5, No. 1, Latest Polymer Synthesis, Sigma-Aldrich Japan).

ATRP polymerization allows the terminal OH group of a sugar to be halogenated and a metal complex [(CuCl, CuCl₂, CuBr, CuBr₂, CuI, or the like)+TPMA (tris(2-pyridylmethyl)amine)], MeTREN (tris[2-(dimethylamino)ethyl]amine), or the like), a monomer (e.g., styrene monomer), and a polymerization initiator (2,2,5-trimethyl-3-(1-phenylethoxy)-4-phenyl-3-azahexane) to react so as to synthesize a sugar copolymer (e.g., sugar-styrene block copolymer).

In NMP polymerization, an alkoxyamine derivative is heated as an initiator to cause a reaction with coupling with a monomer molecule so as to generate a nitroxide. Thereafter, radicals are generated by thermal dissociation to promote the polymerization reaction. Such NMP polymerization is a type of living radical polymerization reaction. A polystyrene-polysaccharide methacrylate random copolymer can be synthesized by mixing a monomer (e.g., a sugar methacrylate compound in which methacrylic acid is added to the terminal position β-1 of a xylooligosaccharide-styrene monomer) and 2,2,6,6-tetramethylpiperidine 1-oxyl (TEMPO) as an initiator, followed by heating at 140° C.

The click reaction is a 1,3-dipolar azide/alkyne cycloaddition reaction using a sugar having a propargyl group and a Cu catalyst. In this case, a linking group having the following structure may be provided between the polymerized portion a and the polymerized portion b.

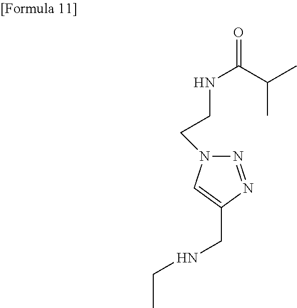 [SMILES: CCNCc1cn(CCNC(=O)C(C)C)nn1]

<Organic Solvent>

The pattern-forming material of the present invention may further contain an organic solvent. However, the pattern-forming material may further contain an aqueous solvent such as water or various aqueous solutions, in addition to the organic solvent. Examples of the organic solvent include an alcohol solvent, an ether solvent, a ketone solvent, a sulfur-containing solvent, an amide solvent, an ester solvent, and a hydrocarbon solvent. These solvents may be used either singly or in combination of two or more types.

Examples of an alcohol solvent include: methanol, ethanol, n-propanol, i-propanol, n-butanol, i-butanol, sec-butanol, tert-butanol, n-pentanol, i-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, Furfuryl alcohol, phenol, cyclohexanol, methylcyclohexanol, 3,3,5-trimethylcyclohexanol, benzyl alcohol, and diacetone alcohol; ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, 1H,1H-trifluoroethanol, 1H,1H-pentafluoropropanol, and 6-(perfluoroethyl)hexanol.

In addition, examples of a partially etherified polyhydric alcohol solvent include ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, diethylene glycol ethyl methyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether.

Examples of an ether solvent include diethyl ether, dipropyl ether, dibutyl ether, diphenyl ether, and tetrahydrofuran (THF).

Examples of a ketone solvent include acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclopentanone, cyclohexanone, cycloheptanone, cyclooctanone, methylcyclohexanone, 2,4-pentanedione, acetonylacetone, acetophenone, and furfural.

Examples of a sulfur-containing solvent include dimethyl sulfoxide.

Examples of an amide-based solvent include N,N′-dimethylimidazolidinone, N-methylformamide, N,N-dimethylformamide, N,N-diethylformamide, acetamide, N-methylacetamide, N,N-dimethylacetamide, N-methylpropionamide, and N-methylpyrrolidone.

Examples of an ester solvent include diethyl carbonate, propylene carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, propionic acid n-butyl, i-amyl propionate, methyl 3-methoxypropionate, diethyl oxalate, di-n-butyl oxalate, methyl lactate, ethyl lactate, n-butyl lactate, n-amyl lactate, diethyl malonate, dimethyl phthalate, and diethyl phthalate.

Examples of a hydrocarbon solvent include: aliphatic hydrocarbon solvents such as n-pentane, i-pentane, n-hexane, i-hexane, n-heptane, i-heptane, 2,2,4-trimethylpentane, n-octane, i-octane, cyclohexane, and methylcyclohexane; and aromatic hydrocarbon solvents such as benzene, toluene, xylene, mesitylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, and anisole.

Of these, propylene glycol monomethyl ether acetate (PGMEA), N,N-dimethylformamide (DMF), propylene glycol monomethyl ether (PGME), anisole, ethanol, methanol, acetone, methyl ethyl ketone, hexane, tetrahydrofuran (THF), dimethyl sulfoxide (DMSO), 1H,1H-trifluoroethanol, 1H,1H-pentafluoropropanol, 6-(perfluoroethyl)hexanol, ethyl acetate, propyl acetate, butyl acetate, cyclohexanone, furfural, N-methylpyrrolidone, and γ-butyrolactone are more preferable, PGMEA, PGME, THF, butyl acetate, anisole, cyclohexanone, N-methylpyrrolidone, γ-butyrolactone, or DMF is more preferable, and PGMEA is even more preferable. These solvents may be used either singly or in combination of two or more types.

The content of the organic solvent is preferably 10% by mass or more, more preferably 20% by mass or more, and even more preferably 30% by mass or more with respect to the total mass of the pattern-forming material. Moreover, the content of the organic solvent is preferably 99.9% by mass or less, and more preferably 99% by mass or less. By setting the content of the organic solvent within the above range, the coatability of the pattern-forming material can be improved.

<Optional Components>

The pattern-forming material of the present invention may contain optional components as described below.

<<Sugar Derivative>>

The pattern-forming material of the present invention may further contain a sugar derivative, in addition to the polymer. Examples of the sugar derivative include a xylose derivative, a xylooligosaccharide derivative, a glucose derivative, a cellulose derivative, and a hemicellulose derivative. Among them, at least one selected from a xylooligosaccharide derivative and a glucose derivative is more preferable.

The pattern-forming material of the present invention may further contain a monomer having a structure derived from a sugar derivative, in addition to the polymer. The monomer containing a structure derived from a sugar derivative is preferably one represented by the formula (1′) or the formula (2′) described later. Note that, in the formulae (1′) and (2′), the structure of a sugar derivative is described as a cyclic structure, but the structure of a sugar derivative is not limited to a cyclic structure and may be an open ring structure (chain structure) called aldose or ketose.

The structure represented by the formula (1′) will be described below.

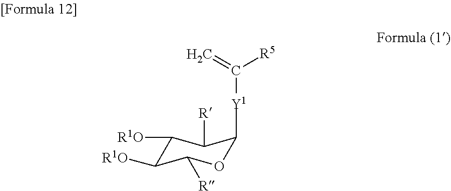

In the formula (1′), each R¹ independently represents a hydrogen atom, a fluorine atom, a chlorine atom, a bromine atom, an iodine atom, an alkyl group, an acyl group, an aryl group, a trimethylsilyl group, or a phosphoryl group, the alkyl group may include a sugar derivative group, and a plurality of R¹ may be the same or different.

R′ represents a hydrogen atom, —OR¹¹, or —NR¹²₂.

R″ represents a hydrogen atom, —OR¹¹, —COOR¹³, or —CH₂OR¹³. Here, R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, and a plurality of R¹² may be the same or different, and R³ represents a hydrogen atom, an alkyl group, an acyl group, an aryl group, a trimethylsilyl group, or a phosphoryl group.

R⁵ represents a hydrogen atom or an alkyl group.

Each Y¹ independently represent a single bond or a linking group;

In the formula (1′), specific aspects and preferable aspects of R¹, R′, R″, R⁵, and Y¹ are the same as those of R¹, R′, R″, R⁵, and Y¹ in the formula (1), respectively. In order to effectively carry out polymerization, at least one R¹ is preferably an acyl group, an aryl group, or a trimethylsilyl group, and more preferably an acyl group which is especially-COCH₃ or —COC₂H₅.

The structure represented by the formula (2′) will be described below.

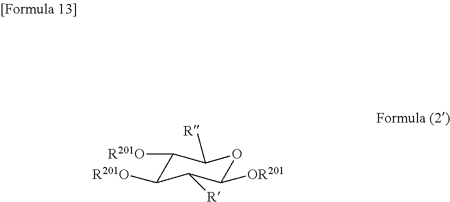

In the formula (2), each R²⁰¹ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R² may be the same or different;

R′ represents a hydrogen atom, —OR¹¹, or —NR¹²₂.

R″ represents a hydrogen atom, —OR¹¹, —COOR¹³, or —CH₂OR¹³. Here, R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, and a plurality of R¹² may be the same or different, and R¹³ represents a hydrogen atom, an alkyl group, an acyl group, an aryl group, a trimethylsilyl group, or a phosphoryl group.

In the formula (2), preferable ranges of R²⁰¹, R′, and R″ are the same as the preferable ranges of R¹, R′, and R″ in the formula (1). In order to effectively carry out polymerization, at least one R is preferably an acyl group, an aryl group, or a trimethylsilyl group, and more preferably an acyl group which is especially —COCH₃ or —COC₂H₅.

The present invention may also relate to a monomer for a pattern-forming material. Specifically, the present invention may relate to a monomer containing a structure derived from a sugar derivative used as a pattern-forming material. Alternatively, it may relate to a monomer for a pattern-forming material having a structure represented by the formula (1′) or (2′).

<<Crosslinkable Compound>>

The pattern-forming material of the present invention may further contain a crosslinkable compound. A pattern-forming film formed by a crosslinking reaction becomes strong, and etching resistance can be more effectively enhanced.

The crosslinkable compound is not particularly limited, but a crosslinkable compound having at least two crosslinkable substituents is preferably used. A compound having two or more, for example, 2 to 6, at least one crosslinkable substituent selected from an isocyanate group, an epoxy group, a hydroxymethylamino group, and an alkoxymethylamino group can be used as the crosslinkable compound.

Examples of the crosslinkable compound include a nitrogen-containing compound having two or more, for example, 2 to 6, nitrogen atoms substituted with a hydroxymethyl group or an alkoxymethyl group. Above all, the crosslinkable compound is preferably a nitrogen-containing compound having a nitrogen atom substituted with a group such as a hydroxymethyl group, a methoxymethyl group, an ethoxymethyl group, a butoxymethyl group, or a hexyloxymethyl group. Specific examples thereof include nitrogen-containing compounds such as hexamethoxymethyl melamine, tetramethoxymethyl benzoguanamine, 1,3,4,6-tetrakis(butoxymethyl)glycoluril,1,3,4,6-tetrakis(hydroxymethyl)glycoluril,1,3-bis(hydroxymethyl)urea, 1,1,3,3-tetrakis(butoxymethyl)urea, 1,1,3,3-tetrakis(methoxymethyl)urea, 1,3-bis(hydroxymethyl)-4,5-dihydroxy-2-imidazolinone, 1,3-bis(methoxymethyl)-4,5-dimethoxy-2-imidazolinone, dicyclohexylcarbodiimide, diisopropylcarbodiimide, di-tert-butylcarbodiimide, and piperazine.

In addition, as the crosslinkable compound, commercially available compounds such as methoxymethyl-type melamine compounds (trade name: CYMEL-300. CYMEL® 301, CYMEL® 303, and CYMEL® 350), butoxymethyl-type melamine compounds (trade name: MYCOATO® 506 and MYCOAT® 508), glycoluril compounds (trade name: CYMEL® 1170 and POWDERLINK® 1174), methylated urea resins (trade name: UFR65), and butylated urea resins (trade name: UFR300, U-VAN10S60, U-VAN10R, and U-VAN11HV) manufactured by Mitsui Cytec Ltd., and urea/formaldehyde resins (trade name: BECKAMINE J-300S, BECKAMINE P-955, and BECKAMINE N) manufactured by Dainippon Ink and Chemicals Inc. can be used. Moreover, as the crosslinkable compound, a polymer produced using an acrylamide compound or a methacrylamide compound substituted with a hydroxymethyl group or an alkoxymethyl group such as N-hydroxymethyl acrylamide, N-methoxymethyl methacrylamide, N-ethoxymethyl acrylamide, or N-butoxymethyl methacrylamide can be used.

Only one type of compound may be used as a crosslinkable compound. Alternatively, two or more types of crosslinkable compounds may be used in combination.

These crosslinkable compounds can cause a crosslinking reaction by self-condensation. They may also cause a crosslinking reaction with the constitutional units contained in a polymer.

<<Catalyst>>

An acid compound such as p-toluenesulfonic acid, trifluoromethanesulfonic acid, pyridinium-p-toluenesulfonic acid, salicylic acid, sulfosalicylic acid, citric acid, benzoic acid, ammonium dodecylbenzenesulfonate, or hydroxybenzoic acid can be added to the pattern-forming material as a catalyst for promoting the crosslinking reaction. Examples of the acid compound may include aromatic sulfonic acid compounds such as p-toluenesulfonic acid, pyridinium-p-toluenesulfonic acid, sulfosalicylic acid, 4-chlorobenzenesulfonic acid, 4-hydroxybenzenesulfonic acid, benzenedisulfonic acid, 1-naphthalenesulfonic acid, and pyridinium-1-naphthalenesulfonic acid. In addition, an acid generator such as 2,4,4,6-tetrabromocyclohexadienone, benzoin tosylate, 2-nitrobenzyl tosylate, bis(4-tert-butylphenyl)iodonium trifluoromethanesulfonate, triphenylsulfonium trifluoromethanesulfonate, phenyl-bis(trichloromethyl)-s-triazine, benzoin tosylate. N-hydroxysuccinimide trifluoromethanesulfonate, bis-(t-butylsulfonyl)diazomethane, or cyclohexylsulfonyldiazomethane can be added.

<<Light Antireflection Agent>>

The pattern-forming material of the present invention may further contain a light antireflection agent. As a light antireflection agent, for example, a light-absorbing compound can be mentioned. Examples of a light-absorbing compound may include those having high light-absorbing ability in the photosensitive characteristic wavelength region of a photosensitive component in a photoresist provided on the light antireflection film such as a benzophenone compound, a benzotriazole compound, an azo compound, a naphthalene compound, an anthracene compound, an anthraquinone compound, and a triazine compound. Examples of a polymer may include polyester, polyimide, polystyrene, novolac resin, polyacetal, and acrylic polymer. Examples of a polymer having a light-absorbing group linked by a chemical bond include a polymer having a light-absorbing aromatic ring structure such as an anthracene ring, a naphthalene ring, a benzene ring, a quinoline ring, a quinoxaline ring, or a thiazole ring.

<<Other Components>>

The pattern-forming material may further contain an ionic liquid, a surfactant, and the like. By incorporating an ionic liquid in the pattern-forming material, the compatibility between a polymer and an organic solvent can be increased.

By including a surfactant in the pattern-forming material, the coatability of the pattern-forming material on a substrate can be improved. Further, when forming a pattern using the pattern-forming material, it is possible to improve coatability of a resist composition or the like applied subsequently to the pattern-forming material. Examples of a preferable surfactant include a nonionic surfactant, a fluorine surfactant, and a silicone surfactant.

In addition, any known material such as a rheology modifier and an adhesion aid may be included in the pattern-forming material.

The content of the optional component as described above is preferably 10% by mass or less, and more preferably 5% by mass or less with respect to the total mass of the pattern-forming material.

(Pattern-Forming Film)

The present invention may relate to a pattern-forming film formed from the above-described pattern-forming material. The pattern-forming film is used when forming a pattern on a substrate or the like, and is a film that can function as a protective film when etching treatment is performed on the substrate. Examples of the pattern-forming film include an underlayer film, a self-assembled film, and a resist film. A pattern-forming film processed into a pattern shape is also referred herein to as a “protective film,” but such a protective film is also included in the pattern-forming film. That is to say, the pattern-forming film includes a layered film before patterning and an intermittent film after patterning

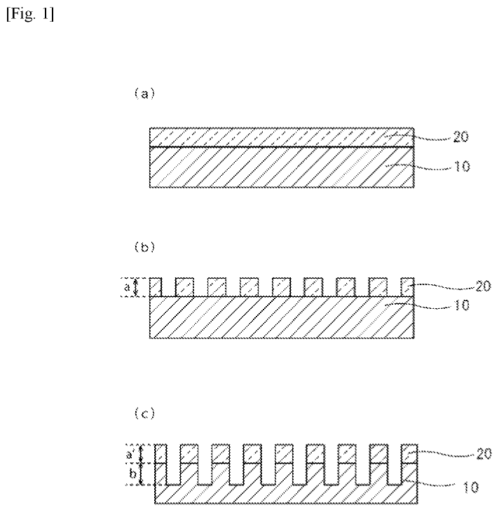

The underlayer film is a layer provided on a substrate such as a silicon wafer. FIG. 1(a) illustrates a laminated body in which an underlayer film 20 is formed on a substrate 10. Although not shown, the underlayer film is preferably a layer provided in an underlayer of a resist film described later. That is to say, the underlayer film is preferably a layer provided between the substrate and the resist film. The underlayer film can also function as a layer for preventing the interaction between the substrate and the resist film, a layer for preventing a material used for the resist film or a substance generated during exposure to the resist film form adversely affecting the substrate, a layer for preventing diffusion of a substance generated from the substrate during heating and baking into the resist film, a barrier layer for reducing poisoning effects of the resist film by a semiconductor substrate dielectric layer, or the like. The underlayer film also functions as a flattening material for flattening the substrate surface. In a case where the pattern-forming film is the underlayer film, the above-described pattern-forming material is also referred to as a “pattern-forming material for underlayer film formation.”

As shown in FIG. 1(b), at least a part of the underlayer film 20 is removed so as to have a pattern shape to be formed on the substrate 10. For example, by laminating a resist film on the underlayer film 20 and performing exposure and development treatment, a pattern shape as shown in FIG. 1(b) can be formed. Then, a pattern as shown in FIG. 1(c) is formed on the substrate 10 by performing reactive ion etching with inductively coupled plasma or the like on the exposed substrate 10 using chlorine gas, boron trichloride, tetrafluoromethane gas, trifluoromethane gas, hexafluoroethane gas, octafluoropropane gas, sulfur hexafluoride gas, argon gas, oxygen gas, or helium gas.

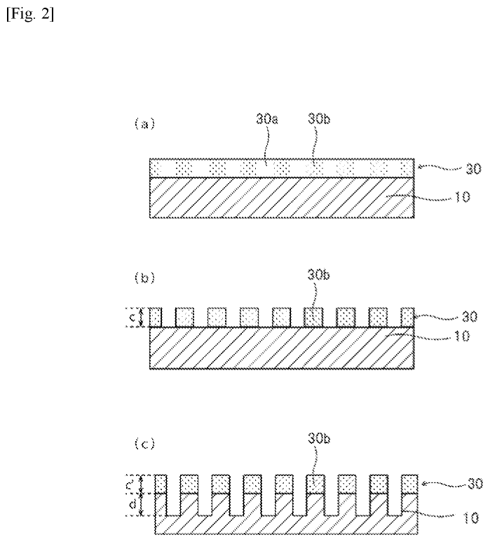

A self-assembled film is also a layer provided on a substrate such as a silicon wafer like the underlayer film. Here, the self-assembled film is a film that can spontaneously construct an assembly or structure without being caused only by control from an external factor. For example, a pattern can be formed by forming a film having a phase-separated structure due to self-assembly (self-assembled film) by applying a pattern-forming material on a substrate and performing annealing or the like, and removing a part of the phase in the self-assembled film. For example, as shown in FIG. 2(a), a self-assembled film 30 is phase-separated into a hydrophobic portion 30a and a hydrophilic portion 30b, for example. Then, the hydrophobic portion 30a is removed by performing reactive ion etching with inductively coupled plasma using oxygen gas, argon gas, helium gas, nitrogen gas, tetrafluoromethane gas, trifluoromethane gas, hexafluoroethane gas, octafluorofluoride gas, or sulfur hexafluoride gas, wet etching using alcohol or acid, or the like such that only the hydrophilic portion 30b remains on the substrate 10 (FIG. 2(b)). The pattern thus formed can serve as a protective film for the substrate. When forming a self-assembled film from the pattern-forming material, the polymer contained in the pattern-forming material is preferably a block copolymer such that a phase-separated structure can be formed. In a case where the pattern-forming film is a self-assembled film, the above-described pattern-forming material is also referred to as a “pattern-forming material for self-assembled film formation.”

In a case where a self-assembled film is provided on the substrate, the substrate may be etched without forming a resist film described later on the self-assembled film.

The resist film is a layer provided on a substrate such as a silicon wafer and is a film having photosensitivity. The resist film is irradiated with far-ultraviolet light having a short wavelength through a mask on which a circuit pattern is drawn, and the pattern is transferred by altering portions of the resist film exposed to the light (exposure). Then, the exposed portions are melted with a developer to form a protective film for the substrate. In a case where the pattern-forming film is a resist film, the above-described pattern-forming material is also referred to as a “pattern-forming material for resist film formation.”

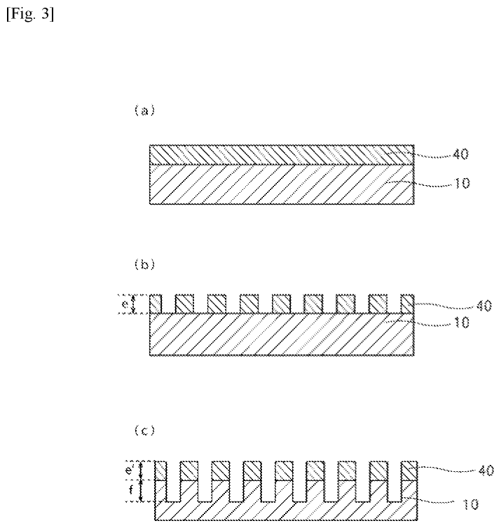

FIG. 3(a) shows a laminated body in which a resist film 40 is formed on a substrate 10. As shown in FIG. 3(b), at least a part of the resist film 40 is removed so as to have a pattern shape to be formed on the substrate 10. For example, by performing exposure and development treatment on the resist film 40, a pattern shape as shown in FIG. 3(b) can be formed. Then, a pattern as shown in FIG. 3(c) is formed on the substrate 10 by performing reactive ion etching with inductively coupled plasma or the like on the exposed substrate 10 using chlorine gas, boron trichloride, tetrafluoromethane gas, trifluoromethane gas, hexafluoroethane gas, octafluoropropane gas, sulfur hexafluoride gas, argon gas, oxygen gas, or helium gas.

The film thickness of the pattern-forming film can be appropriately adjusted depending on the application, but is preferably 1 nm to 20000 nm, more preferably 1 nm to 10000 nm, even more preferably 1 nm to 5000 nm, and particularly preferably 1 nm to 3000 nm.

The pattern-forming film is preferably a film into which a metal has been introduced, and as a result, it is preferable that the pattern-forming film contains a metal. The metal content in the pattern-forming film is preferably 5 at % or more, more preferably 10 at % or more, even more preferably 20 at % or more, and particularly preferably 22 at % or more. The metal content can be calculated, for example, by the following method. First, a pattern-forming film is placed in an atomic layer deposition apparatus (ALD), and Al(CH₃)₃, gas is introduced therein at 95° C., and then steam is introduced. By repeating this operation three times, Al is introduced into the pattern-forming film. EDX analysis (energy dispersive X-ray analysis) is performed on the pattern-forming film after introduction of Al by using an electron microscope JSM7800F (manufactured by JEOL Ltd.) to calculate an Al component ratio (Al content ratio), which is used as a metal content.

(Pattern-Forming Method)

The present invention also relates to a pattern-forming method using the pattern-forming material described above. Specifically, the pattern-forming method preferably includes a step of forming a pattern-forming film using the above-described pattern-forming material and a step of removing a part of the pattern-forming film (lithography process).

Further, the pattern-forming method preferably includes a step of introducing a metal into the pattern-forming material and/or the pattern-forming film. Above all, the pattern-forming method more preferably includes a step of introducing a metal into the pattern-forming film.

The pattern-forming method preferably includes a lithographic process prior to the step of introducing a metal. The lithography process preferably includes a step of forming a resist film on the pattern-forming film and a step of removing a part of the resist film and the pattern-forming film to form a pattern.

The pattern-forming method may include a step of forming a light antireflection film in addition to the step of forming a pattern-forming film using the pattern-forming material of the present invention. Particularly in a case where the pattern-forming material does not contain a light antireflection agent, it is preferable that the pattern-forming method includes a step of forming a light antireflection film. However, in a case where the pattern-forming material contains a light antireflection agent, the step of forming a light antireflection film may not be provided.

When the pattern-forming material is a pattern-forming material for self-assembled film formation and a self-assembled film is formed, the pattern-forming method may further include a step of forming a guide pattern on a substrate. The step of forming a guide pattern on a substrate may be provided before the step of applying the pattern-forming material or after the step of applying the pattern-forming material. The step of forming a guide pattern is a step of forming a prepattern on the pattern-forming film formed in the step of applying the pattern-forming material.

The pattern-forming method preferably includes a step of processing a semiconductor substrate using the above-described pattern as a protective film. Such a step is called an etching step.

<Step of Forming Underlayer Film>

The pattern-forming method of the present invention preferably includes a step of forming an underlayer film as a pattern-forming film. The step of forming an underlayer film is a step of applying a pattern-forming material on a substrate to form a pattern-forming film (underlayer film). In a case where the pattern-forming material of the present invention is a material for resist film formation or a material for self-assembled film formation, the step of forming an underlayer film may or may not be included.

Examples of a substrate include substrates of glass, silicon, SiO₂, SiN, GaN, and AlN. Further, a substrate made of an organic material such as PET, PE, PEO, PS, cycloolefin polymer, polylactic acid, or cellulose nanofiber may be used.

The substrate and the underlayer film are preferably laminated so that the layers adjacent to each other in this order are in direct contact with each other, but other layers may be provided between the respective layers. For example, an anchor layer may be provided between the substrate and the underlayer film. The anchor layer is a layer that controls wettability of the substrate and is a layer that enhances adhesiveness between the substrate and the underlayer film. Further, a plurality of layers made of different materials may be sandwiched between the substrate and the underlayer film. Examples of these materials may include, but are not particularly limited to, inorganic materials such as SiO₂, SiN, Al₂O₃, AlN, GaN, GaAs, W, SOC, SOG, Cr, Mo, MoSi, Ta. Ni, Ru, TaBN, and Ag and organic materials such as commercially available adhesives.

When forming the underlayer film, in addition to the pattern-forming material of the present invention, a commercially available underlayer film material may be used. The underlayer film material is not particularly limited, but for example, a material for spin-on-carbon (SOC) or a material for spin-on-glass (SOG) can be used.

The method for applying the pattern-forming material is not particularly limited, but for example, the pattern-forming material can be applied on the substrate by a known method such as spin coating. After applying the pattern-forming material, the pattern-forming material may be cured by exposure and/or heating to form the underlayer film. Examples of radioactive rays used for such exposure include visible light, ultraviolet light, far ultraviolet light, X-ray, electron beam, γ-ray, molecular beam, and ion beam. The temperature for heating the coating film is not particularly limited, but is preferably 90° C. to 550° C.

It is preferable to provide a step of cleaning the substrate before applying the pattern-forming material to the substrate. By cleaning the substrate surface, coatability of the pattern-forming material is improved. As a method of cleaning treatment, a conventionally known method can be used, and examples thereof include oxygen plasma treatment, ozone oxidation treatment, acid-alkali treatment, and chemical modification treatment.

After forming the underlayer film, it is preferable that heat treatment (baking) is performed to form a layer of the underlayer film from the pattern-forming material. In the present invention, the heat treatment is preferably a heat treatment in the air at a relatively low temperature.

The conditions for heat treatment are preferably selected appropriately within the ranges of a heat treatment temperature of 60° C. to 350° C. and a heat treatment time of 0.3 to 60 minutes. Above all, the heat treatment temperature is more preferably 130° C. to 250° C., and the heat treatment time is more preferably 0.5 to 30 minutes and even more preferably 0.5 to 5 minutes.

After forming the underlayer film, the underlayer film may be rinsed with a rinse liquid such as a solvent, if necessary. Since the uncrosslinked portion and the like in the underlayer film are removed by rinse treatment, the film forming property of a film such as a resist formed on the underlayer film can be improved.

In addition, the rinse liquid may be any rinse liquid as long as it can dissolve the uncrosslinked portion, a solvent such as propylene glycol monomethyl ether acetate (PGMEA), propylene glycol monomethyl ether (PGME), ethyl lactate (EL), or cyclohexanone, a commercially available thinner solution, or the like can be used.

In addition, post-baking may be performed after washing in order to volatilize the rinse liquid. The temperature condition of this post-baking is preferably 80° to 300° C., and the baking time is preferably 30 seconds to 600 seconds.

The underlayer film formed from the pattern-forming material of the present invention may have absorption for light depending on the wavelength of the light used in the lithography process, and in such a case, it can function as a layer having an effect of protecting the reflected light from the substrate, that is, as a light antireflection film. In a case where the underlayer film is used as a light antireflection film in a lithography process using a KrF excimer laser (wavelength: 248 nm), the pattern-forming material preferably contains a component having an anthracene ring or a naphthalene ring. In a case where the underlayer film is used as a light antireflection film in a lithography process using an ArF excimer laser (wavelength: 193 nm), the pattern-forming material preferably contains a compound having a benzene ring. In addition, in a case where the underlayer film is used as a light antireflection film in a lithography process using an F2 excimer laser (wavelength: 157 nm), the pattern-forming material preferably contain a compound having a bromine atom or an iodine atom.

Further, the underlayer film can also function as a layer for preventing the interaction between the substrate and the photoresist, a layer for preventing a material used for the photoresist or a substance generated during exposure to the photoresist form adversely affecting the substrate, a layer for preventing diffusion of a substance generated from the substrate during beating and baking into the photoresist, a barrier layer for reducing poisoning effects of the photoresist by a semiconductor substrate dielectric layer, or the like. The underlayer film formed from the pattern-forming material also functions as a flattening material for flattening the substrate surface.

<Step of Forming Light Antireflection Film>

In a case where the pattern-forming method is used in a semiconductor manufacturing method, a step of forming an organic or inorganic light antireflection film may be provided before and after the formation of the underlayer film on the substrate. In this case, a light antireflection film may be further provided in addition to the underlayer film.

The composition for a light antireflection film used for forming the light antireflection film is not particularly limited, and can be arbitrarily selected and used from those commonly used in the lithography process. Further, a light antireflection film can be formed by a commonly used method, for example, coating with a spinner or a coater and baking. Examples of the composition for a light antireflection film include a composition containing a light-absorbing compound and a polymer as main components, a composition containing a polymer having a light-absorbing group linked by a chemical bond and a cross-linking agent as main components, a composition containing a light-absorbing compound and a cross-linking agent as main components, and a composition containing a light-absorbing polymer crosslinking agent as main components. These compositions for a light antireflection film also contain an acid component, an acid generator component, a rheology modifier, and the like, if necessary. As a light-absorbing compound, those having high light-absorbing ability in the photosensitive characteristic wavelength region of a photosensitive component in a photoresist provided on the light antireflection film can be used. Examples thereof include a benophenone compound, a benzotriazole compound, an azo compound, a naphthalene compound, an anthracene compound, an anthraquinone compound, and a triazine compound. Examples of a polymer may include polyester, polyimide, polystyrene, novolac resin, polyacetal, and acrylic polymer. Examples of a polymer having a light-absorbing group linked by a chemical bond include a polymer having a light-absorbing aromatic ring structure such as an anthracene ring, a naphthalene ring, a benzene ring, a quinoline ring, a quinoxaline ring, or a thiazole ring.

A substrate to which the pattern-forming material of the present invention is applied may have an inorganic light antireflection film formed by a CVD method or the like on the surface thereof, and the pattern-forming film may be formed thereon.

<Step of Forming Resist Film>

In the pattern-forming method, it is also preferable to use a pattern-forming material for resist film formation. The step of forming a resist film is preferably a step of forming a photoresist layer. The formation of a photoresist layer is not particularly limited, but a well-known method can be adopted. For example, a photoresist layer can be formed by applying a pattern-forming material for resist film formation onto a substrate or an underlayer film and baking the material.

The pattern-forming material of the present invention may be used as the pattern-forming material for resist film formation, but a resist film may be formed using a commercially available photoresist material. Further, the pattern-forming material of the present invention and a commercially available photoresist material may be used in combination. The commercially available photoresist material is not particularly limited as long as it is sensitive to the light used for exposure. Further, both a negative type photoresist and a positive type photoresist can be used. Examples thereof include: a positive photoresist comprising a novolac resin and 1,2-naphthoquinonediazide sulfonate; a chemically amplified photoresist comprising a binder having a group that decomposes with an acid to increase the alkali dissolution rate and a photoacid generator; a chemically amplified photoresist composed of a low-molecular-weight compound that decomposes with acid to increase the alkali dissolution rate of a photoresist, an alkali-soluble binder, and a photoacid generator; and a chemically amplified photoresist comprising a binder having a group that decomposes with an acid to increase the alkali dissolution rate, a low molecular weight compound that decomposes with an acid to increase the alkali dissolution rate of a photoresist, and a photoacid generator. For example, APEX-E (trade name) manufactured by Shipley Company, Inc., PAR710 (trade name) manufactured by Sumitomo Chemical Industry Company Limited, and SEPR430 (trade name) manufactured by Shin-Etsu Chemical Co., Ltd. can be mentioned.

The step of forming a resist film preferably includes a step of performing exposure through a predetermined mask. KrF excimer laser (wavelength: 248 nm), ArF excimer laser (wavelength: 193 nm), F2 excimer laser (wavelength: 157 nm), extreme ultraviolet light (EUV) (wavelength: 13 nm), and the like can be used for exposure. After exposure, post-exposure bake can be performed if necessary. The post-exposure bake is preferably performed under conditions of a heating temperature of 70° C. to 150° C. and a heating time of 0.3 to 10 minutes.

The step of forming a resist film preferably includes a step of performing development with a developer. Thus, for example, in a case where a positive photoresist is used, the photoresist of the exposed portion is removed and a photoresist pattern is formed. Examples of a developer may include: aqueous solutions of alkali metal hydroxide such as potassium hydroxide and sodium hydroxide; aqueous solutions of quaternary ammonium hydroxide such as tetramethylammonium hydroxide, tetraethylammonium hydroxide, and choline; and alkaline aqueous solutions such as amine solutions of ethanolamine, propylamine, and ethylenediamine. Further, a surfactant or the like can be added to these developers. The development conditions are appropriately selected from a temperature of 5° C. to 50° C. and a time of 10 to 300 seconds.

A resist film may be formed using nanoimprint lithography in addition to the above-described photolithography. In this case, a resist film can be formed by applying a photocurable nanoimprint resist, pressing a pattern-formed mold against the resist, and irradiating with light such as UV.

<Step of Forming Pattern of Underlayer Film>

In the pattern-forming method, it is preferable that a part of the underlayer film is removed using the pattern of the resist film formed in the step of forming a resist film as a protective film. Such a step is called a step of forming a pattern of an underlayer film.

As a method for removing apart of an underlayer film, known methods including reactive ion etching (RIE) such as chemical dry etching or chemical wet etching (wet development) and physical etching such as sputter etching or ion beam etching can be mentioned. It is preferable to remove an underlayer film by, for example, dry etching using gases of tetrafluoromethane, perfluorocyclobutane (C₄F₈), perfluoropropane (C₃F₈), perfluoroethane (C₂F₆), boron trichloride, methane trifluoride, trifluoromethane, carbon monoxide, argon, oxygen, nitrogen, chlorine, helium, sulfur hexafluoride, difluoromethane, nitrogen trifluoride, chlorine trifluoride, and the like.

Further, a chemical wet etching step can be adopted as a step of removing a part of an underlayer film. Examples of a wet etching technique include a method of treatment by a reaction with acetic acid, a method of treatment by a reaction with a mixed solution of alcohol and water such as ethanol or i-propanol, and a method of treatment with acetic acid or alcohol after irradiation with UV light or EB light.

<Step of Introducing Metal>

It is preferable that the pattern-forming method further includes a step of introducing a metal into a pattern-forming film, such as an sequential infiltration synthesis (SIS) method. Examples of a metal to be introduced include Li, Be, Na, Mg, Al, Si, K, Ca. Sc, Ti, V, Cr, Mn, Fe, Co, Ni, Cu, Zn, Ga, Ge. As, Rb. Sr, Y, Zr, Nb, Mo, Ru, Pd, Ag, Cd, In, Sn, Sb, Te, Cs, Ba, La, Hf, Ta, W. Re, Os, Ir, Pt, Au, Hg, Tl, Pb, Bi, Po, Ce, Pr, Nd, Pm, Sm, Eu, Gd, Tb, Dy, Ho, Er, Tm, Yb, and Lu. Such a process can be carried out by, for example, the method described in Journal of Photopolymer Science and Technology Volume 29, Number 5 (2016) 653-657. Further, in the step of introducing a metal, a method for using a metal complex gas or a method for applying a solution containing a metal can be adopted.

The step of introducing a metal is preferably provided, for example, after forming an underlayer film. In one embodiment of the pattern-forming method, it is preferable to provide a step of forming a resist film, a step of forming a pattern of an underlayer film, a step of introducing a metal, and an etching step after forming an underlayer film. However, the step of introducing a metal may be provided before the step of forming an underlayer film. That is to say, the target for metal introduction is not limited to a pattern-forming film, and may be a pattern-forming material. In a case where the pattern-forming material of the present invention is a pattern-forming material for resist film formation, the step of introducing a metal may be provided before forming a resist film and exposing it or after forming a resist film and performing development.

<Etching Step>

In the pattern-forming method, it is preferable that a semiconductor substrate is processed using the pattern of the resist film, the underlayer film, or the self-assembled film described later formed in the above-described step of forming a resist film as a protective film. Such a step is called an etching step.

As a method for processing a semiconductor substrate in the etching step, known methods including reactive ion etching (RIE) such as chemical dry etching or chemical wet etching (wet development) and physical etching such as sputter etching or ion beam etching can be mentioned. It is preferable to process a semiconductor substrate by, for example, dry etching using gases of tetrafluoromethane, perfluorocyclobutane (C₄F₈), perfluoropropane (C₃F₈), trifluoromethane, carbon monoxide, argon, helium, oxygen, nitrogen, chlorine, sulfur hexafluoride, difluoromethane, nitrogen trifluoride, chlorine trifluoride, and the like.

Further, a chemical wet etching step can be adopted in the etching step. Examples of a wet etching technique include a method comprising treatment by a reaction with acetic acid, a method comprising treatment by a reaction with a mixed solution of alcohol and water such as ethanol or i-propanol, and a method comprising treatment with acetic acid or alcohol after irradiation with UV light or EB light.

<Pattern Forming Method Using Self-Assembled Film>

In a case where a self-assembled film is formed as a pattern-forming film, self-assembled phase separation may be carried out by performing heat treatment after forming a self-assembled film without providing the <Step of Forming Underlayer Film> and the <Step of Forming Resist Film> described above. After a phase-separated self-assembled film is obtained, it is preferable to provide a step of removing a partial phase of the self-assembled film.

The step of applying a pattern-forming material on a substrate may further include a step of forming a guide pattern or a guidepost on the substrate. Further, a step of providing a base layer may be included. The guide pattern may have a hole shape or a linear concave-convex shape. In a case where the guide pattern has a hole shape, the inner diameter is, for example, preferably 1 nm to 300 nm, and more preferably 5 nm to 200 nm. In a case where the guide pattern has a linear concave-convex shape, the width of the concave portion is preferably 1 nm to 300 nm, and more preferably 5 nm to 200. The guide pattern needs to have a pattern shape equal to or larger than the pattern to be formed.

The material of a member for forming a guide pattern is not particularly specified, but may be an inorganic material such as Si, SiO₂, Al₂O₃, AlN, GaN, or glass, or a commercially available resist material may be used. When forming the guide pattern, the same method as a known resist pattern-forming method can be used.

The step of applying a pattern-forming material on a substrate may further include a step of forming a base layer on the substrate. The base layer may be a base film for controlling the surface energy for the purpose of improving the phase separation performance and adhesion of the self-assembled film. As such abase film, for example, a material obtained by synthesizing each monomer unit of the pattern-forming material by random polymerization can be used. An underlayer film can also be used as a base layer.

In the step of causing self-assembled phase separation, annealing or the like is preferably performed on the self-assembled film. In the annealing step, polymers having the same properties are aggregated to spontaneously form an ordered pattern so as to form a self-assembled film having a phase-separated structure such as a sea-island structure, a cylinder structure, a co-continuous structure, or a lamellar structure. Examples of the annealing method include a method of heating at a temperature of 80° C. to 400° C. by an oven, a hot plate, a microwave, or the like. The annealing time is usually 10 seconds to 30 minutes. For example, in a case where heating is performed by a hot plate, it is preferable to perform annealing treatment at 100° C. to 300° C. for 10 seconds to 20 minutes.

The step of removing a partial phase of a self-assembled film is performed by etching treatment using the difference in the etching rate between the phases separated by self-assembly. As a method for removing a partial phase of a self-assembled film in the etching step, known methods including reactive ion etching (RIE) such as chemical dry etching or chemical wet etching (wet development) and physical etching such as sputter etching or ion beam etching can be mentioned.

In a case where a self-assembled film is formed as a pattern-forming film, it is preferable that a step of introducing a metal is provided after the step of removing a partial phase of the self-assembled film, following which the etching step is provided.

<Use of Pattern>

The pattern formed as described above is also preferably used as a guide for patterning using a self-assembled pattern-forming material (DSA: directed self-assembly lithography). It is also preferably used as a mold for nanoimprint lithography.

Further, the pattern-forming method can be applied to various manufacturing methods. For example, the pattern-forming method may be used in semiconductor manufacturing steps. An example of a semiconductor manufacturing method preferably includes a step of forming a pattern on a semiconductor substrate by the pattern-forming method.

### EXAMPLES

The characteristics of the present invention are further specifically described with reference to Examples and Comparative Examples given hereinunder. In the following Examples, the material used, its amount and ratio, the details of the treatment and the treatment process may be suitably modified or changed not overstepping the spirit and the scope of the invention. Accordingly, the invention should not be restrictively interpreted by the specific examples mentioned below.

Note that p, q, l, and n in Examples of the block copolymer each indicate the number of links at polymerization sites, but p, q, l, and n in the Examples of the random copolymer each indicate the number of constitutional units contained in the copolymer.

[Preparation of Sugars]

Xylooligosaccharides, xylotriose, and xylose were obtained by extracting from wood pulp with reference to JP Patent Publication No. 2012-100546 A.

[Synthesis of Sugar Methacrylate 1]

10 g of xylotriose was added to a mixed solution of 120 g of acetic anhydride and 160 g of acetic acid, and the mixture was stirred at 30° C. for 2 hours. Cold water in an amount about 5 times the solution was added slowly with stirring, and the mixture was stirred for 2 hours and then left standing overnight. 10 g of precipitated crystals were added to a solution prepared by adding 0.6 g of ethylenediamine and 0.7 g of acetic acid to 200 mL of THF in a flask and bringing the temperature to 0° C., and the mixture was stirred for 4 hours. The resulting solution was poured into 500 mL of cold water and extracted twice with dichloromethane. 10 g of this extract, 150 mL of dichloromethane, and 2.4 g of triethylamine were placed in a flask and cooled to −30° C. 1.4 g of methacryloyl chloride was added, and the mixture was stirred for 2 hours. The resulting mixture was poured into 150 mL of cold water, extracted twice with dichloromethane, and the solvent was concentrated to obtain 8.1 g of sugar methacrylate 1. The structure of the obtained sugar methacrylate 1 is as follows.

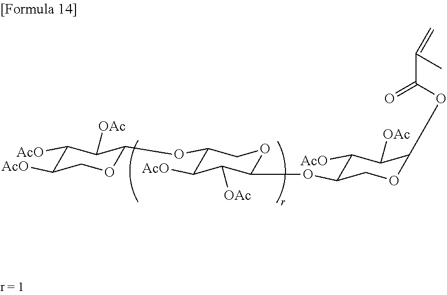

[Polymer Synthesis]

<Synthesis of Polymer 1>

A flask containing 1.3 g of copper (I) bromide (manufactured by Wako Pure Chemical Industries, Ltd.) was purged with nitrogen, and 100 mL of toluene (manufactured by Wako Pure Chemical Industries, Ltd.), 2.8 g of N-propyl-2-pyridylmethanimine, 14 g of styrene, 48 g of sugar methacrylate 1, and 138 g of methyl methacrylate were added, the mixture was heated to 90C with stirring. Then, 1.4 g of ethyl 2-bromoisobutyrate was added, and the mixture was heated for 8 hours. After polymerization, the reaction was terminated by cooling, and the reaction solution diluted by adding THF to the reaction flask was passed through an alumina column to remove the catalyst, and then poured into methanol to precipitate the polymer. THF and methanol were used for performing reprecipitation purification three times and filtering and drying the precipitate, thereby obtaining polymer 1. The structures of the constitutional units (a), (b), and (c) contained in the obtained polymer 1 are as follows.

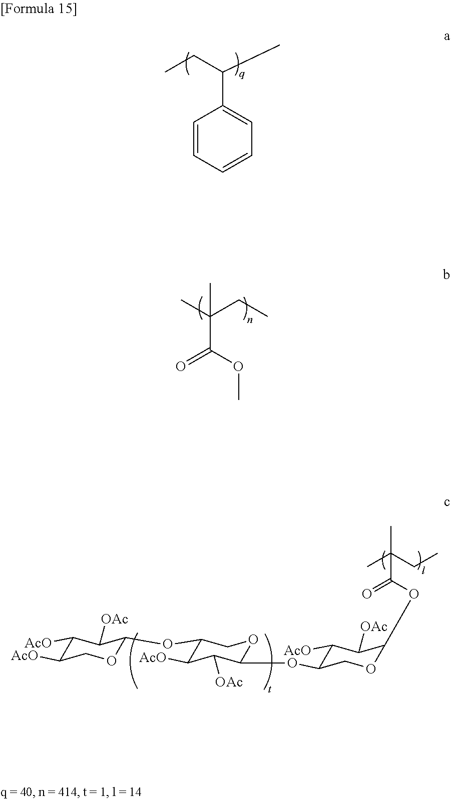

<Synthesis of Polymer 2>

Polymer 2 was synthesized in the same manner as with polymer 1, except that 126 g of 2-acetoacetoxyethyl methacrylate was used instead of 48 g of sugar methacrylate 1 and 138 g of methyl methacrylate in the synthesis of polymer 1. The structures of the constitutional units contained in the obtained polymer 2 are as follows.

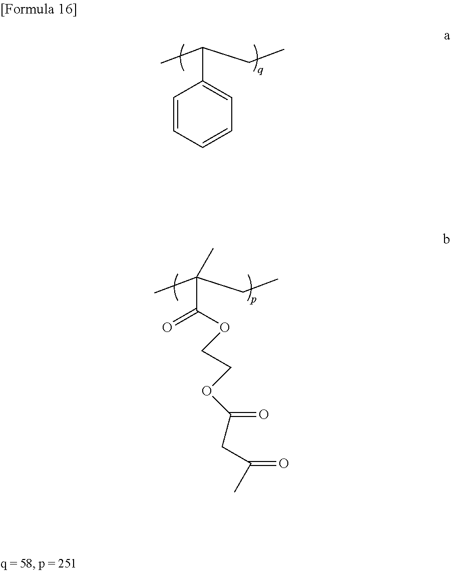

<Synthesis of Polymer 3>

500 mL of tetrahydrofuran and 92 g of a THF solution (manufactured by Tokyo Chemical Industry Co., Ltd.) containing 2.6% by mass of lithium chloride were added to a flask and cooled to −78° C. under an argon atmosphere. 13 g of a hexane solution (manufactured by Tokyo Chemical Industry Co., Ltd.) containing 15.4% by mass of n-butyllithium was added thereto, and the mixture was stirred for 5 minutes and then dehydrated and degassed. Next, 18.8 g of styrene (manufactured by Wako Pure Chemical Industries, Ltd.) was added and stirred for 15 minutes, 1 g of diphenylethylene (manufactured by Wako Pure Chemical Industries, Ltd.) was further added and stirred for 5 minutes. 18.8 g of sugar methacrylate 1 was added and stirred for additional 15 minutes. Then, the reaction was terminated by adding 7 g of methanol. The obtained block copolymer was washed, filtered, and concentrated to obtain polymer 3. The structure of the obtained polymer 3 is as follows.

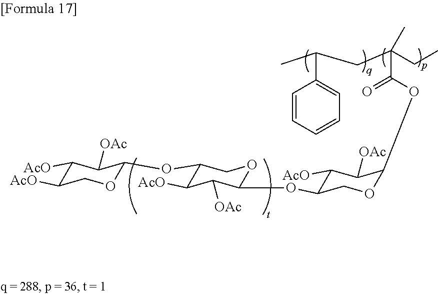

<Synthesis of Polymer 4>

A block copolymer (polymer 4) was obtained in the same manner as in the synthesis of polymer 3, except that 2-acetoacetoxyethyl methacrylate was used instead of sugar methacrylate 1. The structure of the obtained polymer 4 is as follows.

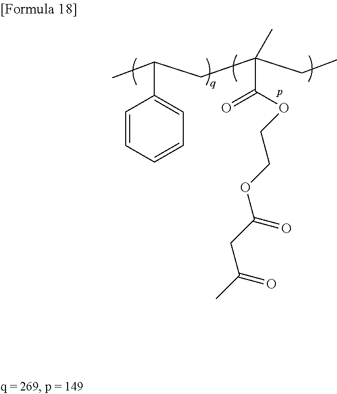

<Synthesis of Polymer 5>

A flask containing 1.3 g of copper (I) bromide (manufactured by Wako Pure Chemical Industries, Ltd.) was purged with nitrogen, and 100 mL of toluene (manufactured by Wako Pure Chemical Industries, Ltd.), 2.8 g of N-propyl-2-pyridylmethanimine, and 100 g of 2-acetoacetoxyethyl methacrylate were added, the mixture was heated to 90° C. with stirring. Then, 1.4 g of ethyl 2-bromoisobutyrate was added, and the mixture was heated for 8 hours. After polymerization, the reaction was terminated by cooling, and the solution diluted by adding THF to the reaction flask was passed through an alumina column to remove the catalyst, and then poured into methanol to precipitate the polymer. THF and methanol were used for performing reprecipitation purification three times and filtering and drying the precipitate, thereby obtaining polymer 5.

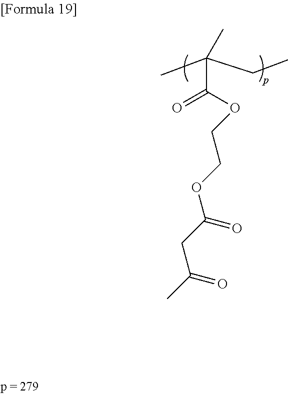

<Synthesis of Polymer 6>

A flask containing 1.3 g of copper (I) bromide (manufactured by Wako Pure Chemical Industries, Ltd.) was purged with nitrogen, and 100 mL of toluene (manufactured by Wako Pure Chemical Industries, Ltd.), 2.8 g of N-propyl-2-pyridylmethanimine, and 140 g of sugar methacrylate 1, and 30 g of methyl adamantyl methacrylate were added, the mixture was heated to 90° C. with stirring. Then, 1.4 g of ethyl 2-bromoisobutyrate was added, and the mixture was heated for 8 hours. After polymerization, the reaction was terminated by cooling, and the solution diluted by adding THF to the reaction flask was passed through an alumina column to remove the catalyst, and then poured into methanol to precipitate the polymer. THF and methanol were used for performing reprecipitation purification three times and filtering and drying the precipitate, thereby obtaining polymer 6. The structures of the constitutional units (a) and (b) contained in the obtained polymer 6 are as follows.

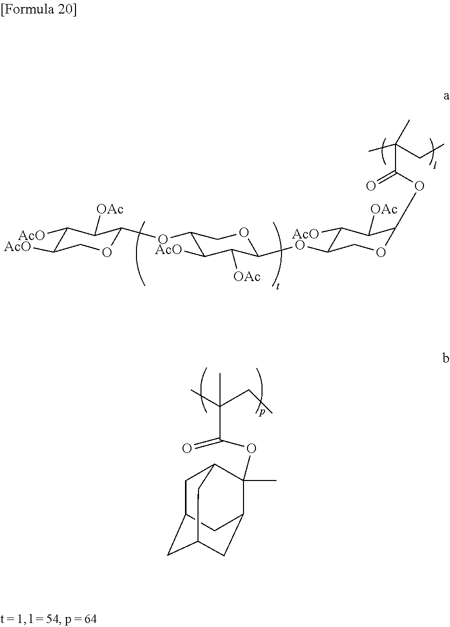

<Synthesis of Polymer 7>

A 300 mL three-necked flask equipped with a thermometer, a condenser, and a magnetic stirrer was charged with 28.3 g of hydroxypyrene, 28.8 g of 1-naphthol, and 12.1 g of paraformaldehyde under a nitrogen atmosphere. Next, 0.57 g of p-toluenesulfonic acid monohydrate was dissolved in 100 g of propylene glycol monomethyl ether acetate (PGMEA), and then this solution was put into the three-necked flask and stirred at 95° C. for 6 hours, thereby carrying out polymeriration. After cooling to room temperature, the reaction solution was poured into a large amount of methanol/water (mass ratio: 800/20) mixed solution. The precipitated polymer was filtered and then dried under reduced pressure at 60° C. overnight, thereby obtaining polymer 7. The structures of the constitutional units (a) and (b) contained in the obtained polymer are as follows.

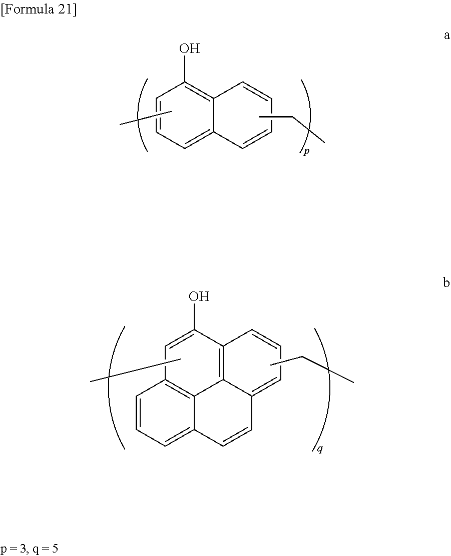

<Synthesis of Polymer 8>

1000 mL of tetrahydrofuran and 92 g of a THF solution (manufactured by Tokyo Chemical Industry Co., Ltd.) containing 2.6% by mass of lithium chloride were added to a flask and cooled to −78° C. under an argon atmosphere. 13 g of a hexane solution (manufactured by Tokyo Chemical Industry Co., Ltd.) containing 15.4% by mass of n-butyllithium was added thereto, and the mixture was stirred for 5 minutes and then dehydrated and degassed. Then, 48 g of styrene was added and stirred for 1 hour, 1 g of diphenylethylene was further added and stirred for 5 minutes, 48 g of methyl methacrylate (manufactured by Wako Pure Chemical Industries, Ltd.) was added and further stirred for 30 minutes. Then, the reaction was terminated by adding 14 g of methanol. The obtained block copolymer was washed, filtered, and concentrated to obtain 55 g of a PS-methyl methacrylate block copolymer (polymer 8). The structure of the obtained polymer 8 is as follows.

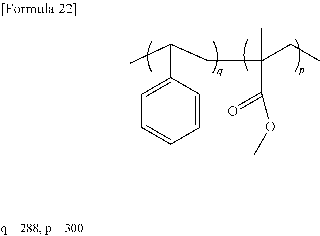

<Synthesis of Polymer 9>

A flask containing 1.3 g of copper (I) bromide (manufactured by Wako Pure Chemical Industries, Ltd.) was purged with nitrogen, and 100 mL of toluene (manufactured by Wako Pure Chemical Industries, Ltd.), 2.8 g of N-propyl-2-pyridylmethanimine, 50 g of γ-butyrolactone methacrylate, and 50 g of methyl adamantyl methacrylate were added, the mixture was heated to 90° C. with stirring. Then, 1.4 g of ethyl 2-bromoisobutyrate was added, and the mixture was heated for 8 hours. After polymerization, the reaction was terminated by cooling, and the solution diluted by adding THF to the reaction flask was passed through an alumina column to remove the catalyst, and then poured into methanol to precipitate the polymer. THF and methanol were used for performing reprecipitation purification three times and filtering and drying the precipitate, thereby obtaining polymer 9. The structures of the constitutional units (a) and (b) contained in the obtained polymer 9 are as follows.

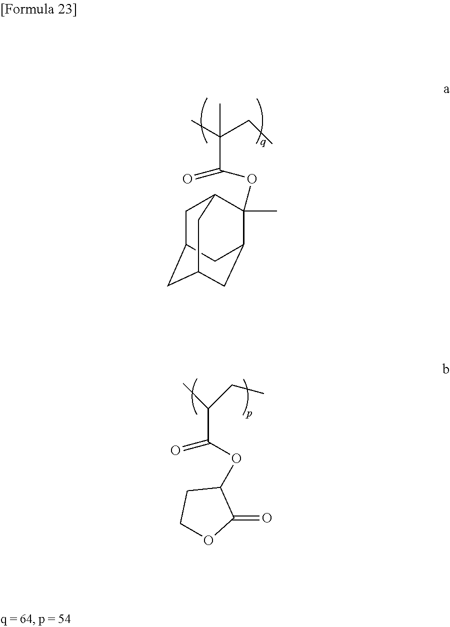

[Polymer Analysis]

<Weight Average Molecular Weight>

The weight average molecular weights of the polymers obtained above were measured by a gel permeation chromatogram (GPC) method.

GPC Column: Shodex K-806M/K-802 Connected column (SHOWA DENKO K.K.) Column temperature: 40° C.

Mobile phase: Chloroform

Detector: RI

When synthesizing a block copolymer (Polymer 3, 4, or 8), the first block (hydrophobic portion (styrene)) was polymerized, a part of the block was taken out to confirm the degree of polymerization using the GPC method, and then, after the next block (hydrophilic portion) was polymerized, the degree of polymerization was confirmed by the GPC method in the same manner, thereby confirming that a block copolymer having a degree of polymerization and a weight average molecular weight as desired was formed. When synthesizing a random copolymer, the degree of polymerization was confirmed by the GPC method after polymerization was completed, thereby confirming that a random copolymer having a degree of polymerization and a weight average molecular weight as desired was formed.

Regarding the molecular weight of each polymer, except for polymer 7, the weight average molecular weight Mw was 60,000. The weight average molecular weight Mw of polymer 7 was 10,000. In addition, PDI in the table is “weight average molecular weight Mw/number average molecular weight Mn.”

<Constitutional Unit Ratio of Copolymer>

The constitutional unit ratio (molar ratio) of the copolymer was determined and calculated by ¹H-NMR.

<Content of Units Derived from Sugar Derivative>

The content of units derived from a sugar derivative was calculated by the following equation.

Content of units derived from sugar derivative (% by mass)=Mass of units derived from sugar derivative×Number of units (monomer) derived from sugar derivative/Weight average molecular weight of polymer

The number of units (monomers) containing a sugar derivative was calculated from the weight average molecular weight of a polymer, the constitutional unit ratio of each structure, and the molecular weight of each structure.

<Oxygen Atom Content>

The oxygen atom content was determined by conducting organic elemental analysis on the polymer powder using a 2400IICHNS/O fully automatic elemental analyzer manufactured by Perkin Elmer Co., Ltd.

TABLE 1

| | | | | | Oxygen |
|---|---|---|---|---|---|
| | | | | | atom |
| | | | | Constitu- | content |
| | | | | tional | (% by |
| | Polymer structure | Mw | PDI | unit ratio | mass) |
| Polymer 1 | PS-co-PXMA-co- | 60,000 | 2.2 | 7-24-69 | 41 |
| | PMMA | | | | |
| Polymer 2 | PS-co-AAEM | 60,000 | 3 | 10-90 | 33 |
| Polymer 3 | PS-b-PXMA | 60,000 | 1.1 | 50-50 | 22 |
| Polymer 4 | PS-b-AAEM | 60,000 | 1.1 | 48-52 | 20 |
| Polymer 5 | 2-Acetoacetoxyethyl | 60,000 | 2 | 100 | 37 |
| | methacrylate | | | | |
| | (AAEM) | | | | |
| Polymer 6 | PXMA-co-MADMA | 60,000 | 2.5 | 75-25 | 36 |
| Polymer 7 | Pyrenol-naphtol | 10,000 | 2.5 | 40-60 | 7 |
| Polymer 8 | PS-b-PMMA | 60,000 | 1.1 | 50-50 | 16 |
| Polymer 9 | GBLMA-MADMA | 60,000 | 2.5 | 25-75 | 19 |

In the table, -co- represents a random copolymer containing each constitutional unit, and -b- represents a block copolymer.

### Examples 1 to 6 and Comparative Examples 1 to 3

<Preparation of Solution Sample>

100 mg of each polymer was dissolved in 2 mL of PGMEA to obtain polymer solution samples (pattern-forming materials) of the Examples and Comparative Examples.

(Evaluation)

<Evaluation of Metal Introduction Rate>

The polymer solution samples (pattern-forming materials) obtained in the Examples and Comparative Examples were separately spin-coated on a 2-inch silicon wafer substrate. After spin-coating was performed to result in a film thickness of 200 nm, each coating was baked at 230° C. for 3 minute on a hot plate to form a polymer film-forming sample.

The polymer film-forming samples thus formed were placed in an ALD (atomic layer deposition apparatus: manufactured by PICUSAN, SUMALE R-100B), Al(CH₃)₃ gas was introduced thereinto at 95° C., and then, steam was introduced thereinto. By repeating this operation three times, Al was introduced into the polymer film-forming samples.

EDX analysis (energy dispersive X-ray analysis) is performed on each polymer film-forming sample after introduction ofAl by using an electron microscope JSM7800F (manufactured by JEOL Ltd.) to calculate an Al component ratio (Al content ratio). The Al content was evaluated to be favorable at 10 at % or more.

### Preparation of Sample for Determining Etching Selectivity of Underlayer Film (Examples 1 and 2 and Comparative Example 1)

Each polymer solution sample (pattern-forming material) was spin-coated on a 2-inch silicon wafer substrate. After spin-coating was performed to result in a film thickness of 200 nm, each coating was baked at 230° C. for 1 minute on a hot plate to obtain an underlayer film sample (FIG. 1(a)).

Each underlayer film sample was masked using an ArF excimer laser exposure machine so as to create a line-and-space (line width: 100 nm; space width: 100 nm) shape, and exposed to light using a commercially available ArF resist. Then, each sample was immersed in a developer after baking at 105° C. for 1 minute on a hot plate, thereby forming a line-and-space pattern.

Each substrate was subjected to oxygen plasma treatment (100 sccm, 4 Pa, 100 W, 60 seconds) with an ICP plasma etching apparatus (manufactured by Tokyo Electron Limited) to remove the photoresist, thereby forming a line-and-space pattern in the underlayer film (FIG. 1(b)). Then, a metal (Al) was introduced into the underlayer film sample in the same manner as in the evaluation of the metal introduction rate of the polymer film-forming sample. Using the ICP plasma etching apparatus (manufactured by Tokyo Electron Limited), each silicon wafer substrate was subjected to plasma treatment (100 sccm, 2 Pa, 1500 W, 20 seconds) using chlorine gas with the pattern of the underlayer film as a mask (FIG. 1(c)).

<Evaluation of Etching Selectivity of Underlayer Film>

The cross section of each patterned silicon wafer substrate before and after chlorine plasma treatment was observed with a scanning electron microscope (SEM) JSM7800F (manufactured by JEOL Ltd.) at an acceleration voltage of 1.5 kV, an emission current of 37.0 μA, and a magnification of 100,000 times. Then, the maximum thickness of the metal-introduced underlayer film and the maximum depth of the processed portion of the silicon wafer substrate were measured. Then, the etching selectivity was calculated by the following equation.

Etching selectivity=Depth of processed portion of silicon wafer substrate/(Thickness of underlayer film before treatment−Thickness of underlayer film after treatment)

The depth of the processed portion of the silicon wafer substrate is the depth represented by “b” in FIG. 1(c), the thickness of the underlayer film before treatment is the thickness represented by “a” in FIG. 1(b), and the thickness of the underlayer film after treatment is the thickness represented by “a” in FIG. 1(c).

TABLE 2

| | | Film | Heating | Al | |
|---|---|---|---|---|---|
| | | thickness | temperature | content | Etching |
| | Polymer | (nm) | (° C.) | (at %) | Selectivity |
| Example 1 | Polymer 1 | 100 | 230 | 30 | 6 |
| Example 2 | Polymer 2 | 100 | 230 | 25 | 5 |
| Comparative | Polymer 7 | 100 | 600 | 1 | 1 |
| Example 1 | | | | | |

Table 2 shows the results when the pattern-forming material was used for the underlayer film used for pattern-forming. In the Examples, the etching selectivity was increased because the metal introduction rate was high.

### Preparation of Samples for Determining Etching Selectivity of Self-Assembled Film (Examples 3 and 4 and Comparative Example 2)

Each polymer solution sample (pattern-forming material) was spin-coated on a 2-inch silicon wafer substrate. After spin-coating was performed to result in a film thickness of 40 nm, each coating was baked at 230° C. for 3 minutes on a hot plate to obtain a self-assembled film which was phase-separated due to self-assembly.

A metal was introduced into the self-assembled film in the same manner as the evaluation of the metal introduction rate in the polymer film-forming sample. The substrate was subjected to oxygen plasma treatment (100 sccm, 4 Pa, 100 W, 30 seconds) with an ICP plasma etching apparatus (manufactured by Tokyo Electron Limited) to remove the hydrophobic portion, thereby forming a lamella pattern on the silicon substrate. Thereafter, using the ICP plasma etching apparatus (manufactured by Tokyo Electron Limited), each silicon wafer substrate was subjected to plasma treatment (100 sccm, 2 Pa, 1500 W, 20 seconds) using chlorine gas with the pattern of the self-assembled film as a mask.

<Evaluation of Etching Selectivity>

The same operation as in <Evaluation of Etching Selectivity of Underlayer Film> was performed, and the etching selectivity was calculated by the following equation.

Etching selectivity=Depth of processed portion of silicon wafer substrate/(Thickness of self-assembled film before treatment−Thickness of self-assembled film after treatment)

The depth of the processed portion of the silicon wafer substrate is the depth represented by “d” in FIG. 2(c), the thickness of the self-assembled film before treatment is the thickness represented by “c” in FIG. 2(b), and the thickness of the self-assembled film after treatment is the thickness represented by “c” in FIG. 2(c).

TABLE 3

| | | Film | Heating | Al | |
|---|---|---|---|---|---|
| | | thickness | temperature | content | Etching |
| | Polymer | (nm) | (° C.) | (at %) | Selectivity |
| Example 3 | Polymer 3 | 40 | 230 | 31 | 10 |
| Example 4 | Polymer 4 | 40 | 230 | 25 | 8 |
| Comparative | Polymer 8 | 40 | 230 | 4 | 2 |
| Example 2 | | | | | |

Table 3 shows the results when the pattern-forming material was used for directed self-assembly lithography (DSA). In the Examples, the etching selectivity was increased because the metal introduction rate was high.

### Preparation of Samples for Determining Etching Selectivity of Resist Film (Examples 5 and 6 and Comparative Example 3)

Each polymer solution sample (pattern-forming material) was spin-coated on a 2-inch silicon wafer substrate. Spin-coating was performed to result in a film thickness of 100 nm, thereby forming a resist film sample.

Each resist film sample was masked using an ArF excimer laser exposure machine so as to create a line-and-space (line width: 100 nm; space width: 100 nm) shape, baked on a plate at 105° C. for 1 minute, and then exposed to light. Then, each sample was immersed in a developer, thereby forming a line-and-space pattern.

Then, a metal was introduced into the resist film sample in the same manner as in the evaluation of the metal introduction rate of the polymer film-forming sample. Thereafter, using the ICP plasma etching apparatus (manufactured by Tokyo Electron Limited), each silicon wafer substrate was subjected to plasma treatment (100 sccm, 2 Pa, 1500 W, 20 seconds) using chlorine gas with the pattern of the resist film as a mask.

<Evaluation of Etching Selectivity>

The same operation as in <Evaluation of Etching Selectivity of Underlayer Film> was performed, and the etching selectivity was calculated by the following equation.

Etching selectivity=Depth of processed portion of silicon wafer substrate/(Thickness of resist film before treatment−Thickness of resist film after treatment)

The depth of the processed portion of the silicon wafer substrate is the depth represented by “f” in FIG. 3(c), the thickness of the resist film before treatment is the thickness represented by “e” in FIG. 3(b), and the thickness of the resist film after treatment is the thickness represented by “e” in FIG. 3(c).

TABLE 4

| | | Film | Heating | Al | |
|---|---|---|---|---|---|
| | | thickness | temperature | content | Etching |
| | Polymer | (nm) | (° C.) | (at %) | Selectivity |
| Example 5 | Polymer 5 | 80 | 200 | 22 | 4 |
| Example 6 | Polymer 6 | 80 | 200 | 21 | 4 |
| Comparative | Polymer 9 | 80 | 200 | 6 | 2 |
| Example 3 | | | | | |

### Example 3

Table 4 shows the results when the pattern-forming material was used for the resist film. In the Examples, the etching selection rate was increased because the metal introduction rate was high.

### REFERENCE SIGNS LIST

10 Substrate
20 Underlayer film
30 Self-assembled film
30a Hydrophobic portion
30b Hydrophilic portion
40 Resist film

1. A pattern-forming material comprising a polymer containing oxygen atoms,
wherein the polymer has an oxygen atom content of 20% by mass or more with respect to the total mass of the polymer, and
the polymer has a silicon atom content of 10% by mass or less with respect to the total mass of the polymer.

2. The pattern-forming material according to claim 1, which is for metal introduction.

3. The pattern-forming material according to claim 1, wherein the polymer contains at least one selected from a unit derived from a sugar derivative and a unit derived from a (meth)acrylate.

4. The pattern-forming material according to claim 1, wherein the polymer contains a unit derived from a sugar derivative.

5. The pattern-forming material according to claim 4, wherein the sugar derivative is at least one selected from a pentose derivative and a hexose derivative.

6. The pattern-forming material according to claim 1, which further comprises an organic solvent.

7. The pattern-forming material according to claim 1, which is used for forming an underlayer film.

8. The pattern-forming material according to claim 1, which is used for forming a self-assembled film.

9. The pattern-forming material according to claim 1, which is used for forming a resist film.

10. A pattern-forming method, comprising:
forming a pattern-forming film using the pattern-forming material according to claim 1; and
removing a part of the pattern-forming film.

11. The pattern-forming method according to claim 10, comprising:
introducing a metal into the pattern-forming film.

12. A monomer for a pattern-forming material, which is represented by the following formula (1′) or the following formula (2′): 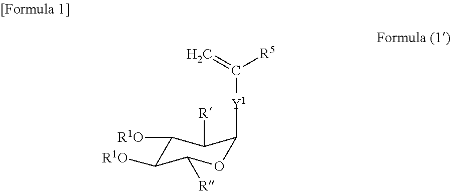
wherein, in the formula (1′), each R independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R¹ may be the same or different;
R′ represents a hydrogen atom, —OR¹¹, or —NR¹²;
R″ represents a hydrogen atom, —OR¹¹, —COOR¹³, or —CH₂OR¹³, provided that R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, a plurality of R¹² may be the same or different, and R represents a hydrogen atom, an alkyl group, an acyl group, an aryl group, a trimethylsilyl group, or a phosphoryl group;
R⁵ represents a hydrogen atom or an alkyl group; and
each Y¹ independently represent a single bond or a linking group; 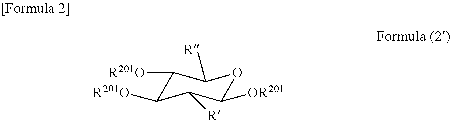
wherein, in the formula (2′), each R²⁰¹ independently represents a hydrogen atom, a fluorine atom, a chlorine atom, a bromine atom, an iodine atom, an alkyl group, an acyl group, an aryl group, a trimethylsilyl group, or a phosphoryl group, and a plurality of R²⁰¹ may be the same or different;
R′ represents a hydrogen atom, —OR¹¹, or —NR¹²₂; and
R″ represents a hydrogen atom, —OR¹¹, —COOR¹³, or —CH₂OR¹³, provided that R¹¹ represents a hydrogen atom, an alkyl group, an acyl group, an aryl group, a trimethylsilyl group, or a phosphoryl group, R¹² represents a hydrogen atom, an alkyl group, a carboxyl group, or an acyl group, a plurality of R¹² may be the same or different, and R¹³ represents a hydrogen atom, an alkyl group, an acyl group, an aryl group, a trimethylsilyl group, or a phosphoryl group.
